(19) United States
(12) Patent Application Publication
(10) Pub. No.: US 2025/0343520 A1
(43) Pub. Date: Nov. 6, 2025

(54) POWER AMPLIFIER CIRCUIT

(71) Applicant: Murata Manufacturing Co., Ltd., Nagaokakyo-shi (JP)

(72) Inventors: Masatoshi KAMITANI, Nagaokakyo-shi (JP); Fumio HARIMA, Nagaokakyo-shi (JP); Yoshiaki SUKEMORI, Nagaokakyo-shi (JP); Yuuki NAKANO, Nagaokakyo-shi (JP); Jong Ik JOO, Nagaokakyo-shi (JP)

(21) Appl. No.: 19/269,129

(22) Filed: Jul. 15, 2025

Related U.S. Application Data
(63) Continuation of application No. PCT/JP2024/000842, filed on Jan. 15, 2024.

(30) Foreign Application Priority Data
Jan. 18, 2023 (JP) 2023-006187

(51) Int. Cl. H03F 3/24; H03F 1/56

(52) U.S. Cl. CPC H03F 3/245; H03F 1/56; H03F 2200/222; H03F 2200/387

(57) ABSTRACT

A power amplifier circuit includes: a first amplifier circuit; a first trigger circuit that includes at least one diode whose anode is electrically connected to the first output terminal; a first conversion circuit that includes a first transistor which is diode-connected, a second transistor current-mirror connected to the first transistor, a first resistor connected in series to a collector or drain of the first transistor, a second resistor connected in series to a collector or drain of the second transistor, and a third resistor connected in series to an emitter or a source of the second transistor; and a first adjustment circuit that includes a transistor of which a base or gate receives a signal outputted from the first conversion circuit, and of which a collector or drain is electrically connected to the first bias circuit so as to adjust the first bias supplied from the first bias circuit.

### CROSS REFERENCE TO RELATED APPLICATION

This is a continuation of International Application No. PCT/JP2024/000842 filed on Jan. 15, 2024 which claims priority from Japanese Patent Application No. 2023-006187 filed on Jan. 18, 2023. The contents of these applications are incorporated herein by reference in their entireties.

### BACKGROUND OF THE DISCLOSURE

### Field of the Disclosure

The present disclosure relates to a power amplifier circuit.

### Description of the Related Art

In a mobile communication terminal such as a mobile phone, a power amplifier circuit is used to amplify a RF (radio frequency) signal to be transmitted to a base station. When the impedance of an antenna of the mobile phone does not match the impedance of the amplifier, for example, the power amplifier circuit will cause the amplifier to fail due to increased output voltage. For example, U.S. Pat. No. 6,580,321 discloses a power amplifier circuit having a protection circuit to protect against such an event.

### BRIEF SUMMARY OF THE DISCLOSURE

In the power amplifier circuit disclosed in U.S. Pat. No. 6,580,321, when the voltage of an output terminal exceeds a certain value, a circuit having a plurality of diodes connected in series will operate. In the power amplifier circuit, a current flowing through the circuit having a plurality of diodes connected in series is supplied to the base of a transistor, thereby suppressing the bias to the amplifier. With such a configuration, the power amplifier circuit can suppress the voltage rise of the output terminal.

However, in the power amplifier circuit disclosed in U.S. Pat. No. 6,580,321, since the diodes operate at a lower voltage as the temperature becomes higher, the circuit having a plurality of diodes connected in series operates earlier as the temperature becomes higher. As a result, the output efficiency of the power amplifier circuit decreases.

The present disclosure has been made in view of such a problem, and it is a possible benefit of the present disclosure to provide a power amplifier circuit capable of suppressing the decrease in output efficiency.

In order to achieve the above possible benefit of the present disclosure, a power amplifier circuit according to an aspect of the present disclosure includes: a first amplifier circuit to which a first bias is supplied from a first bias circuit, and which amplifies a first signal and outputs an output signal to a first output terminal; a first trigger circuit that includes at least one diode whose anode is electrically connected to the first output terminal, and that outputs, when a voltage of the first output terminal exceeds a predetermined threshold, a first feedback signal corresponding to the voltage of the first output terminal; a first conversion circuit that includes a first transistor which is diode-connected, a second transistor current-mirror connected to the first transistor, a first resistor connected in series to a collector or drain of the first transistor, a second resistor connected in series to a collector or drain of the second transistor, and a third resistor connected in series to an emitter or a source of the second transistor, wherein the first feedback signal is inputted to the collector or drain of the first transistor and the collector or drain of the second transistor, and a resistance value of the third resistor is smaller than a resistance value of the second resistor; and a first adjustment circuit that includes a transistor of which a base or gate receives a signal outputted from the first conversion circuit, and of which a collector or drain is electrically connected to the first bias circuit so as to adjust the first bias supplied from the first bias circuit.

In order to achieve the above possible benefit of the present disclosure, a power amplifier circuit according to another aspect of the present disclosure includes: a first amplifier circuit to which a first bias is supplied from a first bias circuit and which amplifies a first signal and outputs an output signal to a first output terminal; a second amplifier circuit to which a second bias is supplied from a second bias circuit, which is electrically connected, in a stage preceding the first amplifier circuit, to the first amplifier circuit, and which amplifies an input signal and outputs the first signal; a first trigger circuit that includes at least one diode whose anode is electrically connected to the first output terminal, and that outputs, when a voltage of the first output terminal exceeds a predetermined threshold, a first feedback signal corresponding to the voltage of the first output terminal; a first conversion circuit that includes a first transistor which is diode-connected, a second transistor current-mirror connected to the first transistor, a first resistor connected in series to a collector or drain of the first transistor, a second resistor connected in series to a collector or drain of the second transistor, and a third resistor connected in series to an emitter or a source of the second transistor, wherein the first feedback signal is inputted to the collector or drain of the first transistor and the collector or drain of the second transistor, and a resistance value of the third resistor is smaller than a resistance value of the second resistor; and a first adjustment circuit that includes a transistor of which a base or gate receives a signal outputted from the first conversion circuit, and of which a collector or drain is electrically connected to the second bias circuit so as to adjust the second bias supplied from the second bias circuit.

According to the present disclosure, it is possible to provide a power amplifier circuit capable of achieving high output efficiency while preventing the amplifier circuit from being broken.

### BRIEF DESCRIPTION OF THE SEVERAL VIEWS OF THE DRAWINGS

FIG. 1 is a diagram showing a configuration example of a power amplifier circuit according to a first embodiment.

Each of FIGS. 2A, 2B and 2C is a graph showing the characteristics of voltage and current at an output terminal of a power amplifier circuit in which no conversion circuit is provided, and a region in which a transistor in a power stage can be broken.

Each of FIGS. 3A, 3B and 3C is a graph showing the characteristics of voltage and current at an output terminal of a power amplifier circuit disclosed in U.S. Pat. No. 6,580,321, and a region in which a transistor in a power stage can be broken.

Each of FIGS. 4A, 4B and 4C is a graph showing the characteristics of voltage and current at an output terminal of the power amplifier circuit, and a region in which a transistor in a power stage can be broken.

FIG. 5 is a graph showing an example of the relationship between a voltage Vtrig indicated by a feedback signal S1 inputted to a conversion circuit and a voltage Von indicated by a signal outputted from the conversion circuit.

FIG. 6 is a diagram showing the state of the voltage and current at each point in the conversion circuit.

FIG. 7 is a diagram showing the state of the voltage and current at each point in the conversion circuit.

FIG. 8 is a diagram showing the state of the voltage and current at each point in the conversion circuit.

Each of FIGS. 9A, 9B and 9C is a graph showing the efficiency characteristics of the power amplifier circuit according to the first embodiment.

Each of FIGS. 10A, 10B and 10C is a graph showing the efficiency characteristics of the power amplifier circuit disclosed in U.S. Pat. No. 6,580,321.

FIG. 11 is a diagram showing a configuration example of a power amplifier circuit according to a first modification.

Each of FIGS. 12A and 12B is a graph showing the relationship between the voltage and current of an amplifier circuit in the power stage.

FIG. 13 is a graph showing the voltage of the amplifier circuit in a driver stage.

FIG. 14 is a diagram showing a configuration example of a power amplifier circuit according to a second modification.

FIG. 15 is a diagram showing a configuration example of a power amplifier circuit according to a second embodiment.

FIG. 16 is a diagram showing a configuration example of a power amplifier circuit according to a third modification.

FIG. 17 is a diagram showing a configuration example of a power amplifier circuit according to a fourth modification.

FIG. 18 is a diagram showing a configuration example of a power amplifier circuit according to a modification of a third embodiment.

FIG. 19 is a diagram showing a configuration example of a power amplifier circuit according to a fourth embodiment.

FIG. 20 is a diagram showing a configuration example of a power amplifier circuit according to a fifth modification.

FIG. 21 is a diagram showing a configuration example of a power amplifier circuit according to a fifth embodiment.

FIG. 22 is a diagram showing a configuration example of a power amplifier circuit according to a sixth modification.

### DETAILED DESCRIPTION OF THE DISCLOSURE

The embodiments of the present disclosure will be described in detail below with reference to the drawings. Note that identical components are denoted by the same reference signs, and duplicate descriptions will be omitted.

### ===Power Amplifier Circuit 100a According to First Embodiment===

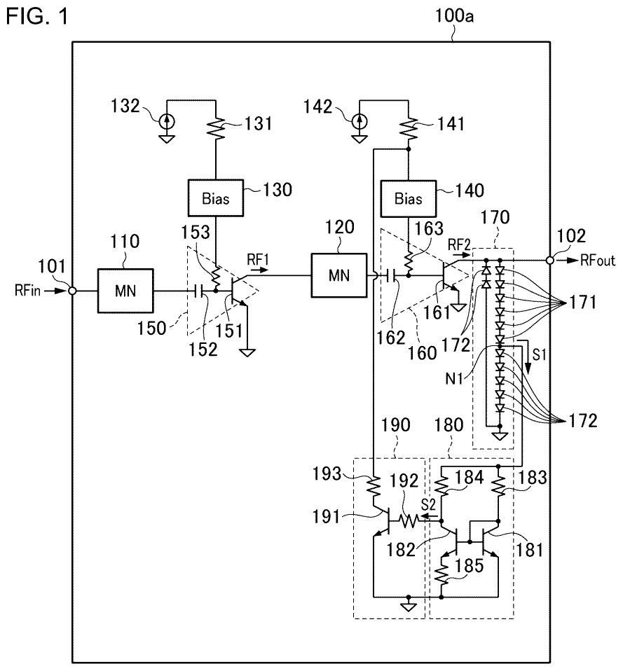

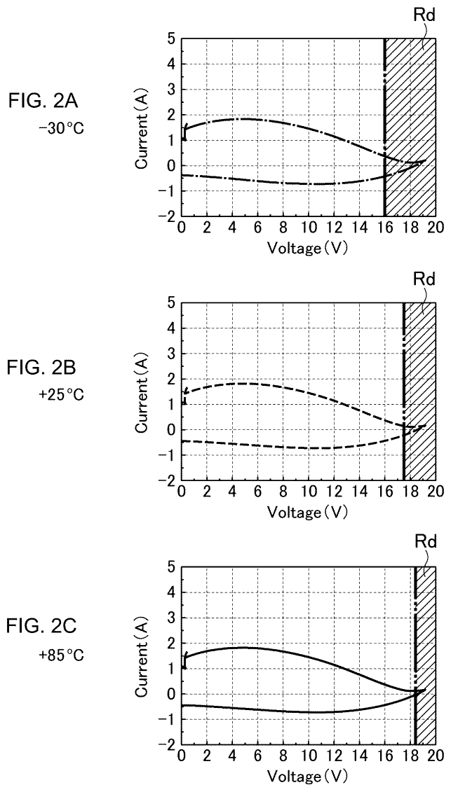

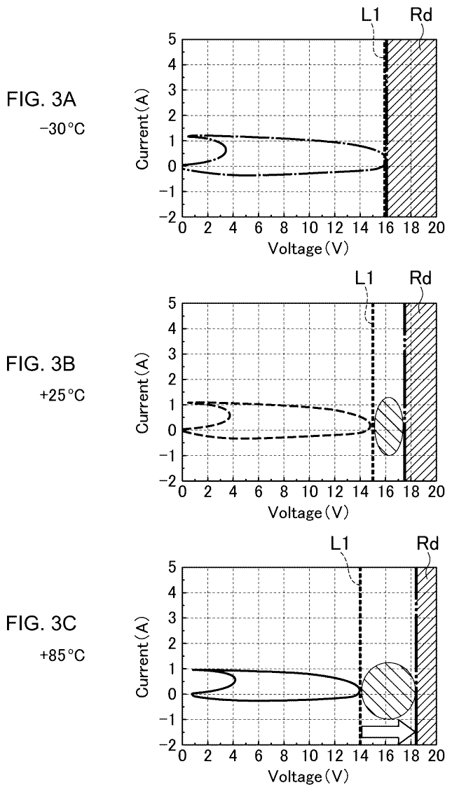

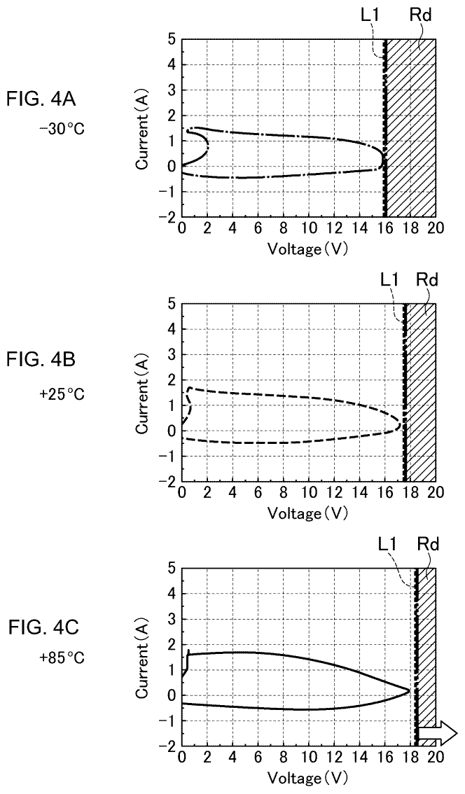

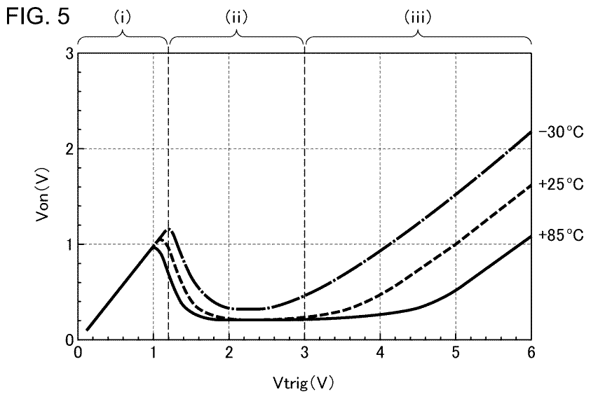

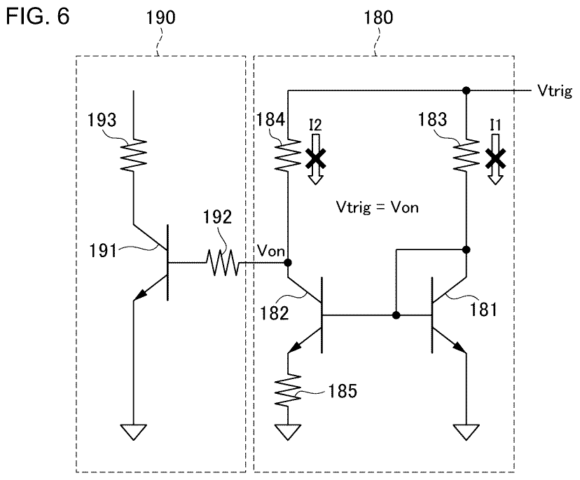

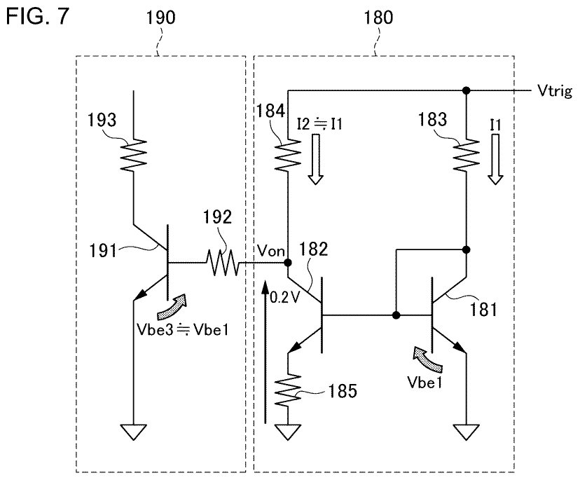

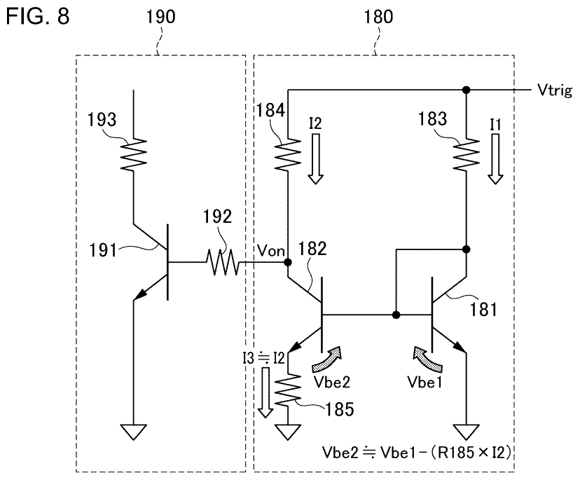

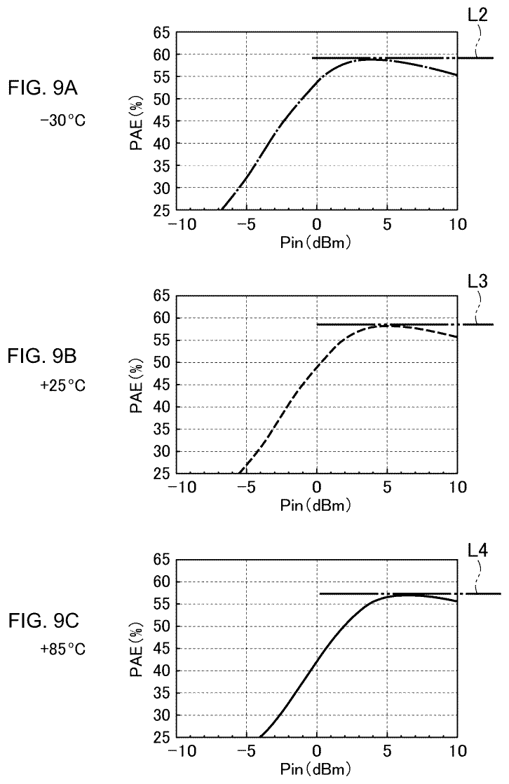

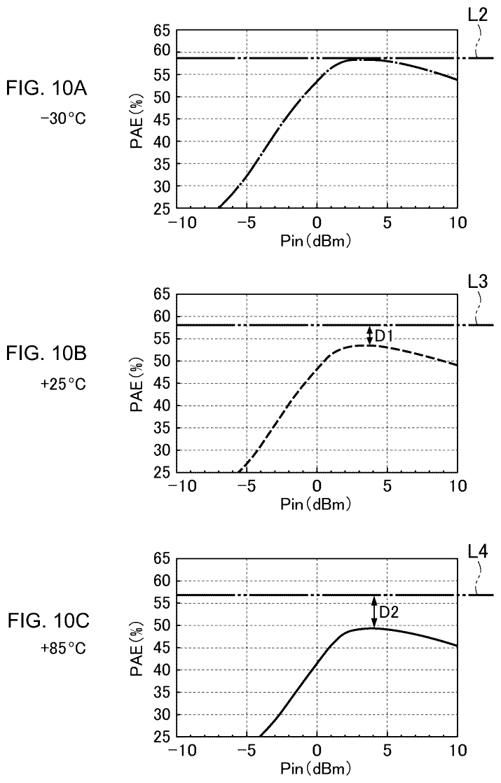

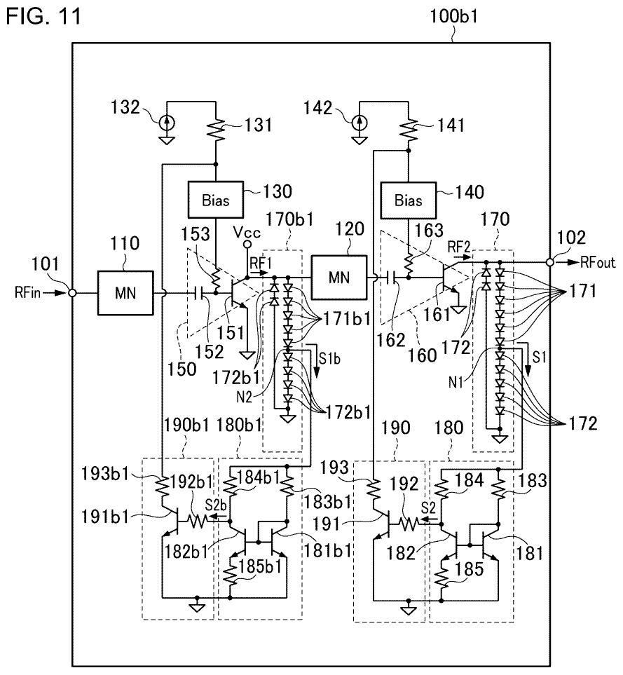

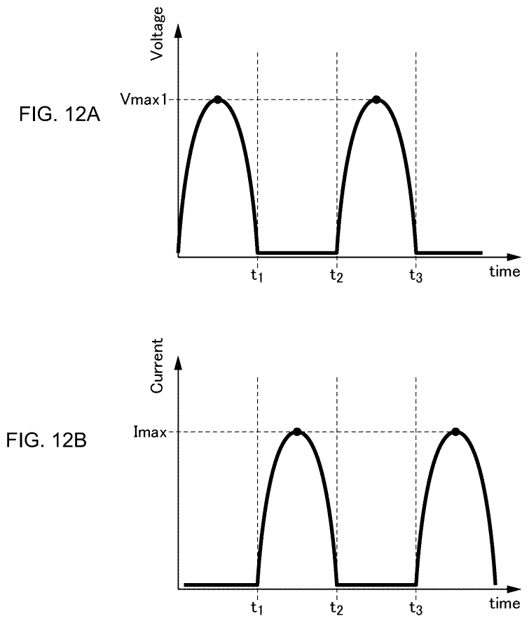

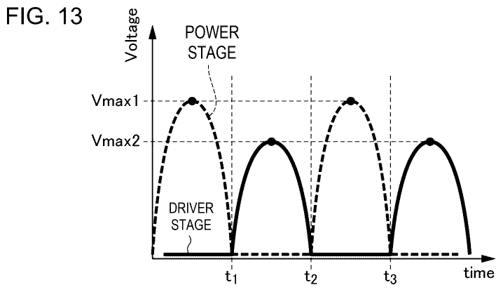

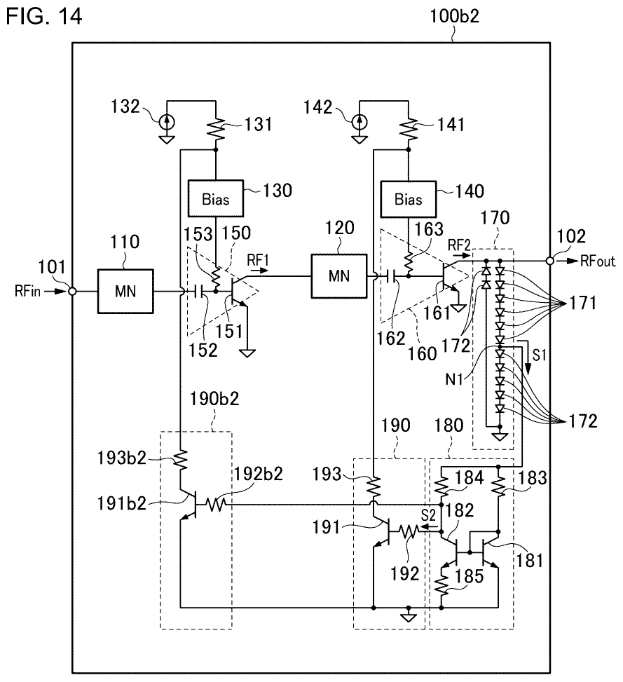

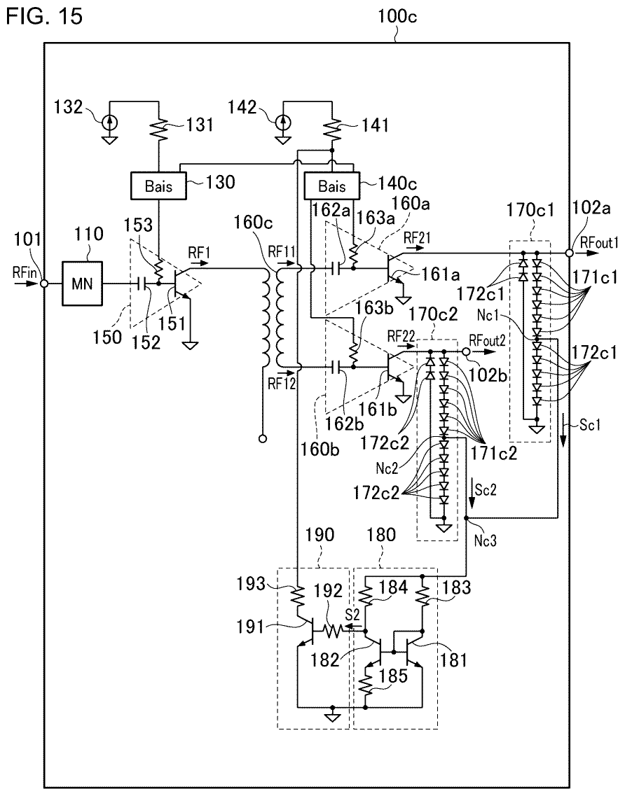

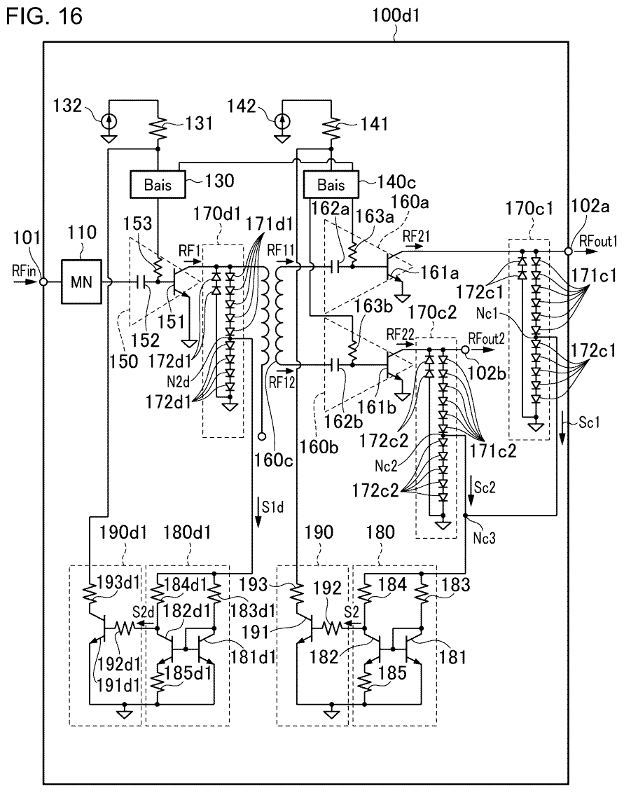

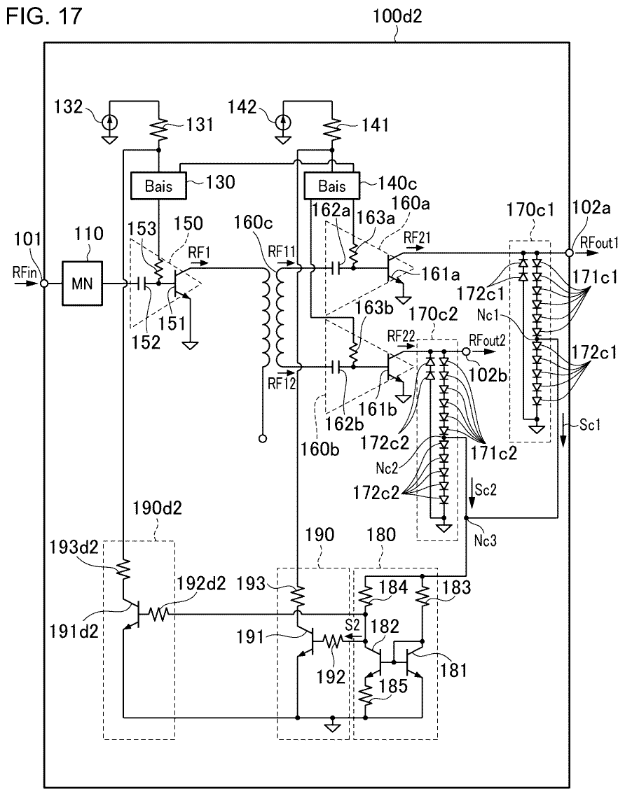

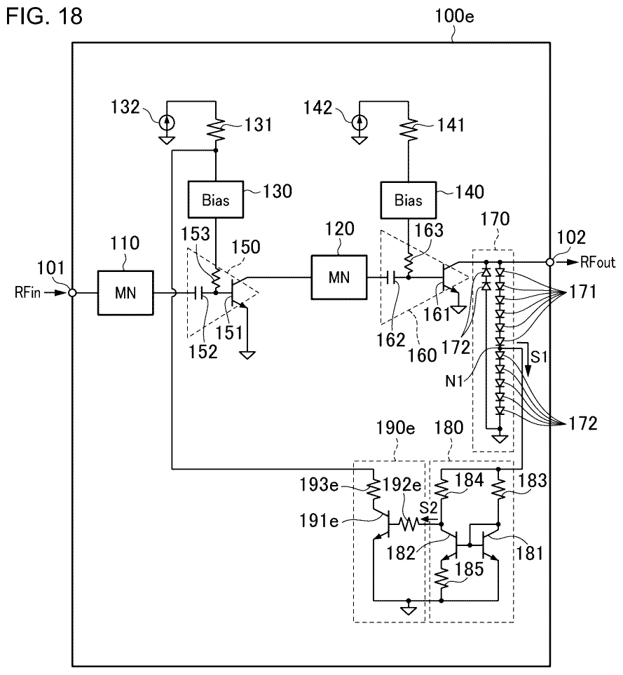

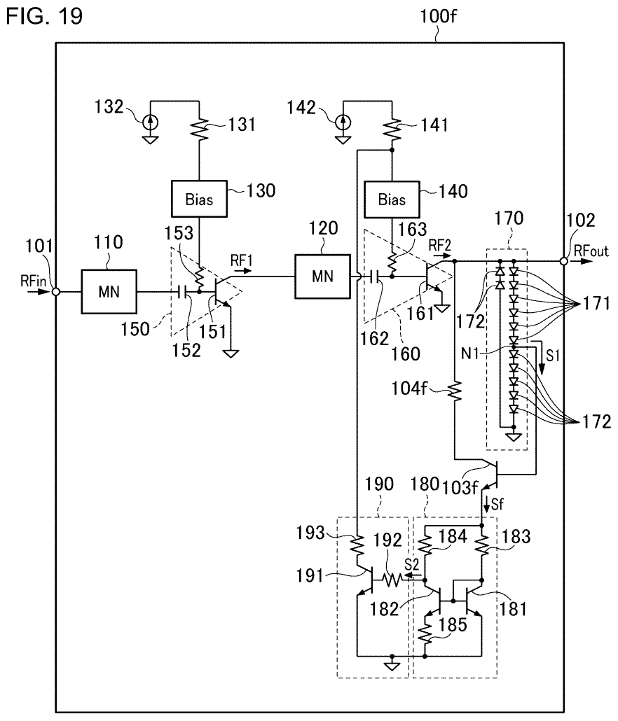

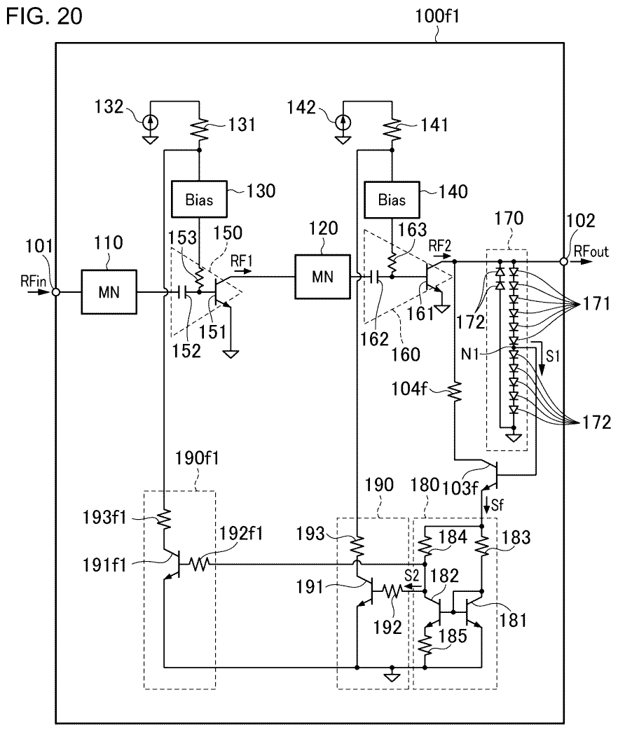

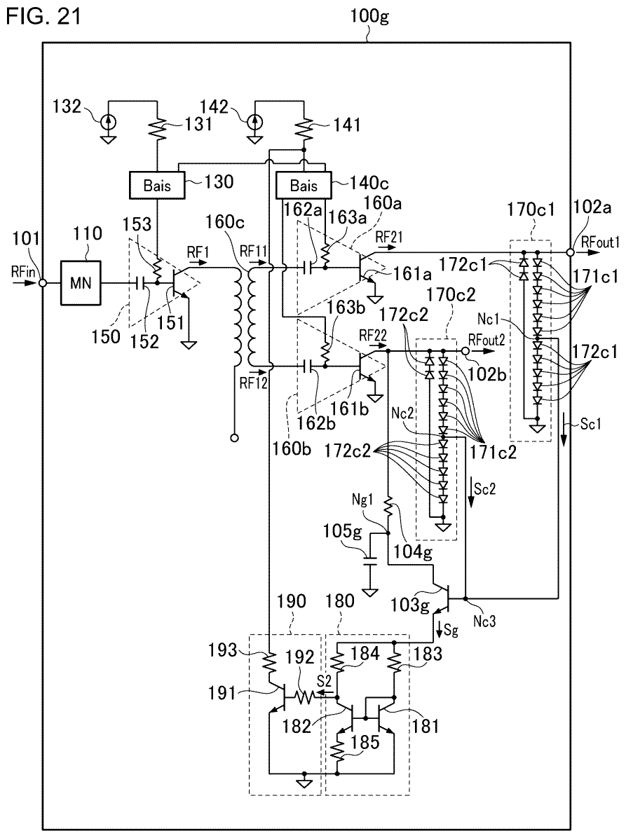

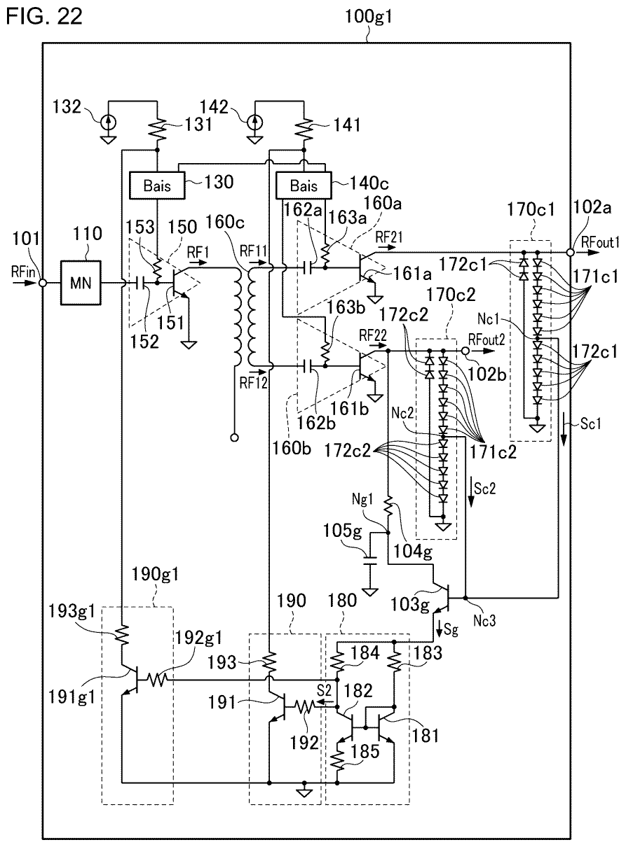

FIG. 1 is a diagram showing a configuration example of a power amplifier circuit 100a according to a first embodiment. The power amplifier circuit 100a shown in FIG. 1 is mounted, for example, on a mobile communication device, such as a mobile phone, to amplify the power of an RF (radio frequency) signal to be transmitted to a base station. The power amplifier circuit 100a amplifies the power of a signal of a communication standard such as 2G (2nd generation mobile communication system), 3G (3rd generation mobile communication system), 4G (4th generation mobile communication system), 5G (5th generation mobile communication system), LTE (Long Term Evolution)-FDD (Frequency Division Duplex), LTE-TDD (Time Division Duplex), LTE-Advanced, LTE-Advanced Pro, and the like. The frequency of the RF signal is, for example, about several hundred MHz to several tens GHz. Note that the communication standard and frequency of the signal amplified by the power amplifier circuit 100a are not limited to those described above.

### <<Configuration>>

An example of the configuration of the power amplifier circuit 100a will be described with reference to FIG. 1.

The power amplifier circuit 100a includes, for example, matching circuits 110 and 120, bias circuits 130 and 140, amplifier circuits 150 and 160, a trigger circuit 170, a conversion circuit 180, and an adjustment circuit 190.

The matching circuit 110 is a circuit (MN: matching network) that matches the impedance of a circuit in a stage preceding the power amplifier circuit 100a with the impedance of the amplifier circuit 150. The matching circuit 120 is a circuit that matches the impedance of the amplifier circuit 150 with the impedance of the amplifier circuit 160.

The bias circuit 130 is a circuit that supplies a bias current to the amplifier circuit 150. For example, the bias circuit 130 receives a constant current from a constant-current source 132 through a resistor 131, and supplies a bias to the base of a transistor 151 of the amplifier circuit 150.

The bias circuit 140 is a circuit that supplies a bias current to the amplifier circuit 160. For example, the bias circuit 140 receives a constant current from a constant-current source 142 through a resistor 141, and supplies a bias to the base of a transistor 161 of the amplifier circuit 160.

The amplifier circuit 150 is a circuit that amplifies an input signal RFin inputted through the matching circuit 110 and outputs a signal RF1. The amplifier circuit 150 includes, for example, the transistor 151, a capacitor 152, and a resistor 153. The input signal RFin is inputted to the base of the transistor 151 through the capacitor 152, and the bias is supplied to the base of the transistor 151 from the bias circuit 130 through the resistor 153.

The amplifier circuit 160 is a circuit that amplifies the signal RF1 inputted through the matching circuit 120 and outputs a signal RF2. The amplifier circuit 160 includes, for example, the transistor 161, a capacitor 162, and a resistor 163. The signal RF1 is inputted to the base of the transistor 161 through the capacitor 162, and the bias is supplied to the base of the transistor 161 from the bias circuit 140 through the resistor 163.

The transistor 151 and the transistor 161 are bipolar transistors such as heterojunction bipolar transistors (HBT), for example. Alternatively, the transistor 151 and the transistor 161 may be configured to include a field-effect transistor (MOSFET: metal-oxide-semiconductor field-effect transistor), instead of the HBT. Hereinafter, as an example, the transistor 151 and the transistor 161 will be described as bipolar transistors.

In the power amplifier circuit 100a, the bias supplied from the bias circuit 140 to the amplifier circuit 160 is adjusted by the adjustment circuit 190, which is to be described later. With such a configuration, in the power amplifier circuit 100a, the voltage of an output terminal 102 is appropriately adjusted according to the temperature.

The trigger circuit 170 is a circuit that outputs, when the voltage of the output terminal 102 exceeds a predetermined threshold, a feedback signal S1 corresponding to the voltage of the output terminal 102 to the conversion circuit 180.

The trigger circuit 170 is composed, for example, of at least one or more diodes. Specifically, in the trigger circuit 170, each of a plurality of diodes is connected in series. The anode of one of the plurality of diodes (in this case, the anode of a diode on one end of the plurality of diodes) is electrically connected to the output terminal 102, and the cathode of one of the plurality of diodes (the cathode of a diode closer to the reference potential side than the diode electrically connected to the output terminal 102) is electrically connected to a reference potential (in this case, the ground). Note that it is sufficient for the trigger circuit 170 to include at least one or more diodes.

In the trigger circuit 170, any node (a node N1 in FIG. 1) between the plurality of diodes connected in series is electrically connected to the conversion circuit 180. In other words, the trigger circuit 170 outputs the feedback signal S1 from the node N1 between two adjacent diodes of the plurality of diodes.

That is, a threshold value is set according to the number of diodes 171 closer to the output terminal 102 side than the node N1, and the trigger circuit 170 outputs the feedback signal S1 through the node N1 when the voltage of the output terminal 102 exceeds such a threshold value.

Further, diodes 172 closer to the reference potential side than the node N1 of the trigger circuit 170 can protect against ESD (electrostatic discharge), which is a high-voltage spike.

In the trigger circuit 170, the threshold value becomes lower as the temperature becomes higher due to the nature of the diode. That is, the trigger circuit 170 operates at a lower voltage of the output terminal 102 at a higher temperature than at a lower temperature.

The power amplifier circuit 100a is provided with the conversion circuit 180 to improve the temperature-dependent operation tendency of the trigger circuit 170.

The conversion circuit 180 includes transistors 181 and 182 and resistors 183,184 and 185. In the conversion circuit 180, the transistor 181 and the transistor 182 are current-mirror connected.

The transistor 181 is a transistor that is diode-connected. The collector of the transistor 181 is electrically connected to the node N1 of the trigger circuit 170, and the feedback signal S1 is inputted to the collector of the transistor 181 through the resistor 183. The emitter of the transistor 181 is electrically connected to the reference potential.

The collector of the transistor 182 is electrically connected to the node N1 of the trigger circuit 170, and the feedback signal S1 is inputted to the collector of the transistor 182 through the resistor 184. The emitter of the transistor 182 is electrically connected to the reference potential through the resistor 185. The base of the transistor 182 is electrically connected to the base of the transistor 181.

The resistor 183 is connected in series between the node N1 of the trigger circuit 170 and the collector of the transistor 181. The resistor 184 is connected in series between the node N1 of the trigger circuit 170 and the collector of the transistor 182.

The resistor 185 is connected in series between the emitter of the transistor 181 and the reference potential. The resistor 185 is a resistor that has a resistance value smaller than that of the resistor 184.

That is, the conversion circuit 180 is a so-called wider current mirror circuit. In the conversion circuit 180, the level of a signal S2 outputted to the adjustment circuit 190 is determined by the ratio of the resistance value of the resistor 184 to the resistance value of the resistor 185. The operation of the conversion circuit 180 will be described later.

The adjustment circuit 190 is a circuit for adjusting the bias outputted from the bias circuit 140 in response to the signal S2 inputted from the conversion circuit 180.

The adjustment circuit 190 includes a transistor 191 and resistors 192 and 193. The transistor 191 has its base electrically connected to the collector of the transistor 182 through the resistor 192, its emitter electrically connected to the reference potential, and its collector electrically connected to the bias circuit 140 so as to suppress the bias outputted from the bias circuit 140.

The transistors 181 and 182 and the transistor 191 are bipolar transistors such as heterojunction bipolar transistors (HBT), for example. Alternatively, the transistors 181 and 182 and the transistor 191 may be configured to include a field-effect transistor (MOSFET: metal-oxide-semiconductor field-effect transistor), instead of the HBT. Hereinafter, as an example, the transistors 181 and 182 and the transistor 191 will be described as bipolar transistors.

### <<Operation>>

Next, the operation of the power amplifier circuit 100a will be described with reference to FIGS. 1 to 11. Hereinafter, the effectiveness of the power amplifier circuit 100a compared with a power amplifier circuit of a comparative example will be described first, and then the specific operation of the power amplifier circuit 100a will be described.

Each of FIGS. 2A, 2B and 2C is a graph showing the characteristics of voltage and current at an output terminal of a power amplifier circuit in which the trigger circuit 170, the conversion circuit 180, and the adjustment circuit 190 are not provided, and a region Rd in which the transistor in the power stage can be broken. In FIGS. 2A, 2B and 2C, the horizontal axis represents the voltage at the output terminal, and the vertical axis represents the current at the output terminal. Further, FIG. 2A is a graph showing the characteristics (one-dot chain line) when the temperature is −30 degrees Celsius. FIG. 2B is a graph showing the characteristics (dashed line) when the temperature is +25 degrees Celsius. FIG. 2C is a graph showing the characteristics (solid line) when the temperature is +85 degrees Celsius.

Each of FIGS. 3A, 3B and 3C is a graph showing the characteristics of voltage and current at an output terminal of a power amplifier circuit disclosed in U.S. Pat. No. 6,580,321, and a region Rd in which the transistor in the power stage can be broken. In other words, each of FIGS. 3A, 3B and 3C is a graph showing the characteristics of voltage and current in a power amplifier circuit obtained by excluding the conversion circuit 180 from the power amplifier circuit 100a according to the first embodiment and a region Rd in which the transistor in the power stage can be broken. In FIGS. 3A, 3B and 3C, the horizontal axis represents the voltage at the output terminal, and the vertical axis represents the current at the output terminal. The region Rd shown in FIGS. 3A, 3B and 3C is the same as the region Rd shown in FIGS. 2A, 2B and 2C. In FIGS. 3A, 3B and 3C, the value of the maximum voltage at the output terminal of the power amplifier circuit is indicated by a dashed line (voltage suppression line L1 to be described later). Further, FIG. 3A shows the characteristics (one-dot chain line) at a temperature of −30 degrees Celsius. FIG. 3B shows the characteristics (dashed line) at a temperature of +25 degrees Celsius. FIG. 3C shows the characteristics (solid line) at a temperature of +85 degrees Celsius.

Each of FIGS. 4A, 4B and 4C is a graph showing the characteristics of voltage and current at the output terminal 102 of the power amplifier circuit 100a, and a region Rd in which the transistor 161 in the power stage can be broken. In FIGS. 4A, 4B and 4C, the horizontal axis represents the voltage at the output terminal 102 and the vertical axis represents the current at the output terminal 102. The region Rd shown in FIGS. 4A, 4B and 4C is the same as the region Rd shown in FIGS. 2A, 2B and 2C. In FIGS. 4A, 4B and 4C, the value of the maximum voltage at the output terminal 102 of the power amplifier circuit 100a is indicated by a dashed line (voltage suppression line L1 to be described later). Further, FIG. 4A shows the characteristics (one-dot chain line) at a temperature of −30 degrees Celsius. FIG. 4B shows the characteristics (dashed line) at a temperature of +25 degrees Celsius. FIG. 4C shows the characteristics (solid line) at a temperature of +85 degrees Celsius.

As shown in FIGS. 2A to 4C, the region Rd in which the transistor can be broken extends to a lower voltage at a lower temperature (−30 degrees Celsius here). That is, the higher the temperature, the higher the voltage in which the transistor can be broken.

As described above, the diodes in the trigger circuit 170 tend to operate faster at higher temperatures. This causes the characteristics of the power amplifier circuit to deteriorate as shown in FIGS. 3A, 3B, 3C, 10A, 10B and 10C, which will be described later. The conversion circuit 180 is a circuit capable of ameliorating the deterioration in the characteristics. The details will be described below.

As shown in FIGS. 2A, 2B and 2C, in the power amplifier circuit in which the conversion circuit 180 is not provided, the voltage of the collector of the transistor in the power stage (the voltage of the output terminal) may indicate the voltage of the region Rd in which the transistor can be broken. That is, in the power amplifier circuit, there is a high risk that the transistor will be broken when the output voltage becomes high.

As shown in FIGS. 3A, 3B and 3C, in the power amplifier circuit disclosed in U.S. Pat. No. 6,580,321, a protection circuit corresponding to the trigger circuit 170 and the adjustment circuit 190 of the power amplifier circuit 100a is provided in order to suppress the voltage of the output terminal. As a result, as shown in a voltage suppression line L1 in FIGS. 3A, 3B and 3C, the protection circuit operates at a lower voltage (i.e., the voltage of the output terminal is lower) as the temperature becomes higher. On the other hand, as shown in the region Rd in FIGS. 3B and 3C, the region Rd shifts to a higher voltage as the temperature becomes higher. Therefore, in the power amplifier circuit, the deviation between the voltage of the output terminal when the protection circuit operates and the voltage indicated by the region Rd becomes larger as the temperature becomes higher. As a result, the characteristics of the power amplifier circuit deteriorate, and the output efficiency becomes lower.

As shown in FIGS. 4A, 4B and 4C, in the power amplifier circuit 100a, the adjustment circuit 190 can be operated by the conversion circuit 180 when the voltage of the output terminal 102 becomes higher as the temperature becomes higher. That is, as shown in FIGS. 4A to 4C, in the power amplifier circuit 100a, the voltage of the output terminal 102 when the adjustment circuit 190 operates shifts to a higher voltage as the temperature becomes higher. Therefore, in the power amplifier circuit 100a, the deviation between the voltage of the output terminal 102 when the adjustment circuit 190 operates and the voltage indicated by the region Rd can be remarkably reduced (or the voltage of the output terminal 102 when the adjustment circuit 190 operates is caused to coincide with the voltage indicated by the region Rd).

The operation of the conversion circuit 180, which shifts the voltage of the output terminal 102 when the adjustment circuit 190 operates to a higher voltage as the temperature becomes higher, will be described below with reference to FIGS. 5 to 8.

FIG. 5 is a graph showing an example of the relationship between a voltage Vtrig indicated by the feedback signal S1 inputted to the conversion circuit 180 and a voltage Von indicated by the signal outputted from the conversion circuit 180. In FIG. 5, the horizontal axis represents the voltage Vtrig, and the vertical axis represents the voltage Von.

In FIG. 5, as an example, the characteristic at −30 degrees Celsius is represented by a one-dot chain line, the characteristic at +25 degrees Celsius is represented by a dashed line, and the characteristic at +85 degrees Celsius is represented by a solid line. For convenience of description, in FIG. 5, the operation region of the conversion circuit 180 is divided into an operation region (i), an operation region (ii), and an operation region (iii).

FIGS. 6, 7, and 8 are each a diagram showing the state of the voltage and current at each point in the conversion circuit 180.

First, the operation of the conversion circuit 180 in the operation region (i) will be described with reference to FIGS. 5 and 6.

In a region where the voltage Vtrig shown in the operation region (i) of FIG. 5 is less than 1.2 V, the transistor 181 and the transistor 182 do not operate. That is, as shown in FIG. 6, no current (a current I1 and a current I2 here) flows through the transistor 181 and the transistor 182. Therefore, no voltage drop occurs in the resistor 184. Therefore, the voltage Von, which is the base potential of the transistor 191, is substantially equal to the voltage Vtrig.

Next, the operation of the conversion circuit 180 in the operation region (ii) will be described with reference to FIGS. 5 and 7.

In a region where the voltage Vtrig shown in the operation region (ii) of FIG. 5 exceeds 1.2 V, the current I1 starts to flow in the transistor 181 as shown in FIG. 7. The current value of the current I1 is a value obtained by dividing the difference between the voltage Vtrig and a voltage Vbe1 between the base and emitter of the transistor 181 by the resistance value of the resistor 183. Here, since a voltage Vbe3 between the base and emitter of the transistor 191 is equal to the voltage Vbe1, the current I2 flowing in the transistor 182 is equal to the current I1. In the operation region (ii), since the transistor 182 operates in a saturation region, the voltage Von is about 0.2 V.

Next, the operation of the conversion circuit 180 in the operation region (iii) will be described with reference to FIGS. 5 and 8.

In a region where the voltage Vtrig shown in the operation region (iii) of FIG. 5 exceeds, for example, 3.0 V, the current I2 changes logarithmically with respect to the voltage Vtrig, as shown in FIG. 5. This is because the transistor 182 operates in an active region and, as shown in FIG. 8, the resistor 185 is connected in series to the emitter of the transistor 182 (Vbe2 of the transistor 182 is a value obtained by subtracting the product of the resistor 185 and the current I2 from Vbe1 of the transistor 181). In a region where the voltage Vtrig is even higher (an active region completely outside the saturation region), the voltage Vtrig increases more than the voltage drop in the resistor 184. Therefore, the voltage Von increases substantially in proportion to the voltage Vtrig.

At this time, in the transistor 182, the current on the reference potential side becomes larger as the temperature becomes higher. Therefore, a higher voltage is required for the voltage between the collector and emitter of the transistor 182 as the temperature becomes lower. That is, in the power amplifier circuit 100a, since the collector-emitter voltage Vce of the transistor 182 in the active region becomes higher as the temperature becomes lower, the voltage Von rises at a lower voltage Vtrig (i.e., the voltage Von rises faster).

Thus, as shown in the operation region (iii) of FIG. 5, for the same voltage Vtrig, the voltage of the voltage Von at a lower temperature (for example, −30 degrees Celsius) becomes higher than the voltage of the voltage Von at a higher temperature (for example, +85 degrees Celsius). That is, the higher the temperature, the higher the value of the voltage Vtrig at which the voltage Von rises to a desired value (for example, the voltage Von is 0.7 V). Therefore, as shown in FIGS. 4A, 4B and 4C, the higher the temperature, the transistor 191 of the adjustment circuit 190 can be operated at the higher voltage of the output terminal 102 (in this case, the voltage Vtrig). Thus, the power amplifier circuit 100a can suppress the voltage of the output terminal 102 to the optimum level according to the temperature.

That is, as shown in FIGS. 3A, 3B and 3C, in the power amplifier circuit disclosed in U.S. Pat. No. 6,580,321, the transistor operates in a state where the voltage of the output terminal is lower as the temperature becomes higher, while in the power amplifier circuit 100a, the conversion circuit 180 can operate the transistor 191 of the adjustment circuit 190 in a state where the voltage of the output terminal 102 is higher as the temperature becomes higher.

The resistance value of the resistor 185 is smaller than the resistance value of the resistor 184. The resistance value of the resistor 185 and the resistance value of the resistor 184 are set in such a manner so that the voltage Von rises at an appropriate voltage Vtrig in the operation region (iii) shown in FIG. 5. The larger the ratio of the resistance value of the resistor 185 to the resistance value of the resistor 184, the gentler the logarithmically changing curve of the graph in the operation region (iii) shown in FIG. 5, and therefore the difference of the voltage Vtrig with respect to the same voltage Von becomes larger.

That is, in the power amplifier circuit 100a, the operating timing of the transistor 191 of the adjustment circuit 190 with respect to the voltage Vtrig can be adjusted by adjusting the resistance value of the resistor 185.

Here, the fact that the power amplifier circuit 100a can improve the output efficiency as compared with the power amplifier circuit disclosed in U.S. Pat. No. 6,580,321 will be described below with reference to FIGS. 9A, 9B, 9C, 10A, 10B and 10C. Each of FIGS. 9A, 9B and 9C is a graph showing the efficiency characteristics of the power amplifier circuit 100a according to the first embodiment. Each of FIGS. 10A, 10B and 10C is a graph showing the efficiency characteristics of the power amplifier circuit disclosed in U.S. Pat. No. 6,580,321. In each of FIGS. 9A, 9B, 9C, 10A, 10B and 10C, each of 9A and 10A shows the efficiency characteristics at −30 degrees Celsius, each of 9B and 10B shows the efficiency characteristics at +25 degrees Celsius, and each of 9C and 10C shows the efficiency characteristics at +85 degrees Celsius. In FIGS. 9A, 9B, 9C, 10A, 10B and 10C, the horizontal axis represents the level of the input signal, and the vertical axis represents the efficiency. In FIGS. 9A, 9B, 9C, 10A, 10B and 10C, the efficiency of the power amplifier circuit in which the trigger circuit 170, the conversion circuit 180, and the adjustment circuit 190 are not provided is shown by lines L2 to L4.

As shown in FIGS. 9A to 9C, in the power amplifier circuit 100a, the efficiency is not decreased by the trigger circuit 170, the conversion circuit 180, and the adjustment circuit 190 as compared with the power amplifier circuit not provided with the conversion circuit 180, even if the temperature changes. This is because, as shown in FIGS. 4A, 4B and 4C, in the power amplifier circuit 100a, the maximum voltage of the output terminal 102 can be brought closer to the voltage indicated by the region Rd of the transistor by the conversion circuit 180, according to the temperature.

On the other hand, as shown in FIGS. 10A to 10C, in the power amplifier circuit disclosed in U.S. Pat. No. 6,580,321, the efficiency is decreased (D1 and D2 in FIGS. 10A, 10B and 10C) as compared with the power amplifier circuit not provided with the conversion circuit 180 as the temperature becomes higher. This is because, as shown in FIGS. 3A, 3B and 3C, in the power amplifier circuit disclosed in U.S. Pat. No. 6,580,321, the protection circuit operates when the voltage of the output terminal is lower as the temperature becomes higher.

### <<First Modification>>

A power amplifier circuit 100b1 according to a modification of the first embodiment will be described with reference to FIG. 11. FIG. 11 is a diagram showing a configuration example of the power amplifier circuit 100b1 according to a first modification. Note that, in the following, descriptions of common matters with the power amplifier circuit 100a according to the first embodiment will be omitted, and only the differences will be described. In particular, the same effects achieved by the same configuration will not be described repeatedly.

Compared with the power amplifier circuit 100a, in the power amplifier circuit 100b1, a trigger circuit 170b1, a conversion circuit 180b1, and an adjustment circuit 190b1 are also provided in the collector of the amplifier circuit 150 in the driver stage.

The trigger circuit 170b1 is a circuit that outputs, when the collector voltage of the transistor 151 of the amplifier circuit 150 exceeds a predetermined threshold, a feedback signal S1b corresponding to the collector voltage to the conversion circuit 180b1.

The trigger circuit 170b1 is composed, for example, of at least one or more diodes 171b1 and 172b1. Specifically, in the trigger circuit 170b1, each of a plurality of diodes is connected in series. The anode of the plurality of diodes (in this case, the anode on one end) is electrically connected to the collector of the transistor 151, and the cathode is electrically connected to a reference potential (in this case, the ground).

In the trigger circuit 170b1, any node (a node N2 in FIG. 11) between the plurality of diodes connected in series is electrically connected to the conversion circuit 180b1. In other words, in the trigger circuit 170, the feedback signal S1b is outputted from the node N2 between two diodes connected in series among the plurality of diodes.

That is, a threshold value is set according to the number of diodes 171b1 closer to the collector side than the node N2, and the trigger circuit 170b1 outputs the feedback signal S1b through the node N2 when the collector voltage exceeds the threshold value.

Further, the diode 172b1 closer to the reference potential side than the node N2 of the trigger circuit 170b1 can protect against ESD (electrostatic discharge), which is a high-voltage spike.

In the trigger circuit 170b1, the threshold value becomes lower as the temperature becomes higher due to the nature of the diode. That is, the trigger circuit 170 starts more easily at a higher temperature than at a lower temperature.

The power amplifier circuit 100b1 is provided with the conversion circuit 180b1 to improve the temperature-dependent operation tendency of the trigger circuit 170b1.

The conversion circuit 180b1 includes transistors 181b1 and 182b1 and resistors 183b1, 184b1, and 185b1. Since the conversion circuit 180b1 has the same configuration as the conversion circuit 180, the description thereof is omitted.

The adjustment circuit 190b1 is a circuit for suppressing the bias outputted from the bias circuit 130 in response to a signal S2b inputted from the conversion circuit 180b1.

The adjustment circuit 190b1 includes a transistor 191b1, a resistor 192b1, and a resistor 193b1. Since the adjustment circuit 190b1 has the same configuration as the adjustment circuit 190, the description thereof is omitted.

Next, the operation of the power amplifier circuit 100b1 will be described with reference to FIGS. 11 to 13.

Each of FIGS. 12A and 12B is a graph showing the relationship between the voltage and current of the amplifier circuit 160 in the power stage. In FIG. 12A, the horizontal axis represents time, and the vertical axis represents the collector voltage of the amplifier circuit 160. In FIG. 12B, the horizontal axis represents time, and the vertical axis represents the base current of the amplifier circuit 160.

FIG. 13 is a graph showing the voltage of the amplifier circuit 150 in the driver stage. In FIG. 13, the horizontal axis represents time, and the vertical axis represents the collector voltage of the amplifier circuit 150.

Note that in the following description, with respect to the driver stage of the power amplifier circuit 100b1, the same operations as those in the power stage of the power amplifier circuit 100a shown in FIGS. 5 to 10 are omitted. That is, further operations in the power amplifier circuit 100b1 compared with the power amplifier circuit 100a will be described below.

As shown in FIGS. 12A and 12B, in the power amplifier circuit 100b1, the phase of the collector voltage and the phase of the base current of the amplifier circuit 160 in the power stage differ by approximately 180 degrees.

In the power amplifier circuit 100b1, due to the operation of the conversion circuit 180, the voltage at the time when the voltage amplitude shown in FIG. 12A becomes maximum (Vmax 1 in FIG. 12A) is suppressed so as to prevent the amplifier circuit 160 in the power stage from being broken. However, the current at the time when the current amplitude shown in FIG. 12B becomes maximum (Imax in FIG. 12B) cannot be suppressed by only providing the conversion circuit 180 in the power stage.

In the power amplifier circuit 100b1, by providing the conversion circuit 180b1 also in the driver stage, the transistor is prevented from being broken by the voltage in the driver stage, and the transistor is prevented from being broken by the current in the power stage.

Specifically, as shown in FIG. 13, the phase of the voltage in the driver stage is approximately 180 degrees different from the phase of the voltage in the power stage. That is, the phase of the voltage in the driver stage approximately coincides with the phase of the current in the power stage. Thus, in the power amplifier circuit 100b1, due to the operation of the conversion circuit 180b1, the voltage at the time when the voltage amplitude of the amplifier circuit 150 in the driver stage becomes maximum (i.e., Vmax2 in FIG. 13) is suppressed, and thereby the current at the time when the current amplitude in the power stage becomes maximum (i.e., Imax in FIG. 12B) can be suppressed.

### <<Second Modification>>

A power amplifier circuit 100b2 according to a modification of the first embodiment will be described with reference to FIG. 14. FIG. 14 is a diagram showing a configuration example of the power amplifier circuit 100b2 according to a second modification. Note that, in the following, descriptions of common matters with the power amplifier circuit 100a according to the first embodiment will be omitted, and only the differences will be described. In particular, the same effects achieved by the same configuration will not be described repeatedly.

Compared with the power amplifier circuit 100a, the power amplifier circuit 100b2 further includes an adjustment circuit 190b2 for suppressing the bias of the amplifier circuit 150 in the driver stage.

The adjustment circuit 190b2 is a circuit for suppressing the bias outputted from the bias circuit 130 to the amplifier circuit 150 in response to the signal S1 inputted from the conversion circuit 180. The adjustment circuit 190b2 includes a transistor 191b2, a resistor 192b2, and a resistor 193b2. Since the adjustment circuit 190b2 has the same configuration as the adjustment circuit 190, the description thereof is omitted.

Next, the operation of the power amplifier circuit 100b2 will be described. The power amplifier circuit 100b2 performs the same operation as the operation performed in the power amplifier circuit 100b1 according to the first modification, which is to suppress the voltage amplitude of the collector and the current amplitude of the base (which differs from the voltage amplitude of the collector in phase by approximately 180 degrees) of the amplifier circuit 160 in the power stage. Therefore, the operation of the power amplifier circuit 100b2 will be described below with reference to FIGS. 12A, 12B and 13.

In the power amplifier circuit 100b2, due to the operation of the conversion circuit 180, the voltage at the time when the voltage amplitude shown in FIG. 12A becomes maximum is suppressed so as to prevent the amplifier circuit 160 in the power stage from being broken. However, the current at the time when the current amplitude shown in FIG. 12B becomes maximum (Imax in FIG. 12B) cannot be suppressed by the conversion circuit 180 and the adjustment circuit 190 provided in the power stage.

Therefore, in the power amplifier circuit 100b2, the adjustment circuit 190b2 is provided in parallel with the adjustment circuit 190, so that when the conversion circuit 180 is operated, the voltage at the time when the voltage amplitude of the amplifier circuit 150 in the driver stage (which differs from the voltage amplitude of the collector of the amplifier circuit 160 in the power stage in phase by approximately 180 degrees) becomes maximized (Vmax 2 in FIG. 13) is suppressed through the adjustment circuit 190b2. Thus, in the power amplifier circuit 100b2, the current at the time when the current amplitude in the power stage becomes the maximum (Imax in FIG. 12B) can be suppressed. Further, the power amplifier circuit 100b2 achieves the same effect as the power amplifier circuit 100b1 with a simpler configuration as compared to the power amplifier circuit 100b1.

### ===Power Amplifier Circuit 100c According to Second Embodiment===

A power amplifier circuit 100c according to a second embodiment will be described below with reference to FIG. 15. FIG. 15 is a diagram showing a configuration example of the power amplifier circuit 100c according to the second embodiment. Note that, in the following, descriptions of common matters with the power amplifier circuit 100a according to the first embodiment will be omitted, and only the differences will be described. In particular, the same effects achieved by the same configuration will not be described repeatedly.

Compared with the power amplifier circuit 100a, in the power amplifier circuit 100c, the amplifier circuit 160 in the power stage is formed as a differential amplifier circuit by an amplifier circuit 160a and an amplifier circuit 160b. In the power amplifier circuit 100c, the amplifier circuit 160a and the amplifier circuit 160b are respectively provided with a trigger circuit 170cl and a trigger circuit 170c2.

The power amplifier circuit 100c includes a divider 160c which divides the signal RF1 outputted from the amplifier circuit 150 into a signal RF11 and a signal RF12 whose phase differs by approximately 180 degrees from the signal RF11. The divider 160c is, for example, a balance transformer.

The amplifier circuit 160a amplifies the signal RF11 and outputs a signal RF21 to an output terminal 102a. The amplifier circuit 160b amplifies the signal RF12 and outputs a signal RF22 to an output terminal 102b.

The trigger circuit 170cl is a circuit that outputs, when the voltage of the output terminal 102a exceeds a predetermined threshold, a feedback signal Sc1 corresponding to the voltage of the output terminal 102a to the conversion circuit 180.

The trigger circuit 170cl is composed, for example, of at least one or more diodes 171c1 and 172c1. Specifically, the trigger circuit 170cl includes a plurality of diodes, each of which is connected in series. The anode of the plurality of diodes (in this case, the anode on one end) is electrically connected to the output terminal 102a, and the cathode is electrically connected to a reference potential (in this case, the ground).

In the trigger circuit 170cl, any node (a “node Nc1” in FIG. 15) between the plurality of diodes connected in series is electrically connected to the conversion circuit 180. In other words, in the trigger circuit 170cl, the feedback signal Sc1 is outputted from the node Nc1 between two diodes connected in series among the plurality of diodes.

The trigger circuit 170c2 is a circuit that outputs, when the voltage of the output terminal 102b exceeds a predetermined threshold, a feedback signal Sc2 corresponding to the voltage of the output terminal 102b to the conversion circuit 180.

The trigger circuit 170c2 is composed, for example, of at least one or more diodes 171c2 and 172c2. Specifically, the trigger circuit 170c2 includes a plurality of diodes, each of which is connected in series. The anode of the plurality of diodes (in this case, the anode on one end) is electrically connected to the output terminal 102b, and the cathode is electrically connected to a reference potential (in this case, the ground).

In the trigger circuit 170c2, any node (a node Nc2 in FIG. 14) between the plurality of diodes connected in series is electrically connected to the conversion circuit 180. In other words, in the trigger circuit 170c2, the feedback signal Sc2 is outputted from the node Nc2 between two diodes connected in series among the plurality of diodes.

The feedback signal Sc1 and the feedback signal Sc2 outputted from the trigger circuit 170cl and the trigger circuit 170c2 are combined at a node Nc3. The power amplifier circuit 100c is configured so that the combined signal is inputted to a conversion circuit 180c. Since the configuration of the conversion circuit 180c is the same as that of the conversion circuit 180, the description thereof is omitted.

An adjustment circuit 190c suppresses biases outputted from a bias circuit 140c in response to the signal S2 inputted from the conversion circuit 180c. Since the configuration of the adjustment circuit 190c is the same as that of the adjustment circuit 190, the description thereof is omitted.

The collector of the adjustment circuit 190c is electrically connected to the bias circuit 140c so as to adjust the biases outputted from the bias circuit 140c to the amplifier circuit 160a and the amplifier circuit 160b respectively. When the bias circuit 140c is individually provided to each of the amplifier circuit 160a and the amplifier circuit 160b, the collector of the adjustment circuit 190c may be electrically connected to a portion (For example, in FIG. 14, a node between the resistor 141 and the bias circuit 140c) common to the inputs of respective bias circuits.

In the power amplifier circuit 100c, the circuit can be made resistant to noise by being composed of differential amplifier circuits, and it is possible to prevent the amplifier circuit from being broken while achieving miniaturization by using a common conversion circuit without providing a conversion circuit for each of the amplifier circuits of the differential amplifier circuits.

### <<Third Modification>>

A power amplifier circuit 100d1 according to a modification of the second embodiment will be described below with reference to FIG. 16. FIG. 16 is a diagram showing the power amplifier circuit 100d1 according to a third modification. In the following, descriptions of the common matters with the power amplifier circuit 100c according to the second embodiment will be omitted, and only the differences will be described. In particular, the same effects achieved by the same configuration will not be described repeatedly.

Compared with the power amplifier circuit 100c, the power amplifier circuit 100d1 according to the third modification includes a trigger circuit 170d1, a conversion circuit 180d, and an adjustment circuit 190d also in the collector of the amplifier circuit 150 in the driver stage.

The trigger circuit 170d1 is a circuit that outputs, when the collector voltage of the transistor 151 of the amplifier circuit 150 exceeds a predetermined threshold, a feedback signal S1d corresponding to the collector voltage to the conversion circuit 180d. Since the trigger circuit 170d1 is the same as the trigger circuit 170b1 shown in FIG. 11, the description thereof is omitted.

In the power amplifier circuit 100d1, by providing the conversion circuit 180d also in the driver stage of the power amplifier circuit 100c, the transistor is prevented from being broken by the voltage in the driver stage, and the transistor is prevented from being broken by the current in the power stage as compared with the power amplifier circuit 100c.

### <<Fourth Modification>>

A power amplifier circuit 100d2 according to a modification of the second embodiment will be described below with reference to FIG. 17. FIG. 17 is a diagram showing a configuration example of the power amplifier circuit 100d2 according to a fourth modification. In the following, descriptions of the common matters with the power amplifier circuit 100c according to the second embodiment will be omitted, and only the differences will be described. In particular, the same effects achieved by the same configuration will not be described repeatedly.

Compared with the power amplifier circuit 100c, the power amplifier circuit 100d2 according to the fourth modification further includes an adjustment circuit 190d2 for suppressing the bias of the amplifier circuit 150 in the driver stage.

The adjustment circuit 190d2 is a circuit for suppressing the bias outputted from the bias circuit 130 to the amplifier circuit 150 in response to the signal S2 inputted from the conversion circuit 180. The adjustment circuit 190d2 includes a transistor 191d2, a resistor 192d2, and a resistor 193d2. Since the adjustment circuit 190d2 has the same configuration as the adjustment circuit 190, the description thereof is omitted.

Next, the operation of the power amplifier circuit 100d2 will be described. The power amplifier circuit 100d2 performs the same operation as the operation performed in the power amplifier circuit 100d1 according to the third modification, which is to suppress the voltage amplitudes of the collectors and the current amplitudes of the bases (which differ respectively from the voltage amplitudes of the collectors in phase by approximately 180 degrees) of the amplifier circuit 160a and the amplifier circuit 160b in the power stage. Therefore, the operation of the power amplifier circuit 100b2 will be described below with reference to FIGS. 12A, 12B and 13.

In the power amplifier circuit 100d2, due to the operation of the conversion circuit 180, the voltage at the time when the voltage amplitude shown in FIG. 12A becomes maximum is suppressed so as to prevent the amplifier circuit 160a and the amplifier circuit 160b in the power stage from being broken. However, the current at the time when the current amplitude shown in FIG. 12B becomes maximum (Imax in FIG. 12B) cannot be suppressed by the conversion circuit 180 and the adjustment circuit 190 provided in the power stage.

Therefore, in the power amplifier circuit 100d2, the adjustment circuit 190d2 is provided in parallel with the adjustment circuit 190, so that when the conversion circuit 180 is operated, the voltage at the time when the voltage amplitude of the amplifier circuit 150 in the driver stage becomes maximized (Vmax 2 in FIG. 13) is suppressed through the adjustment circuit 190d2. Thus, in the power amplifier circuit 100b2, the current at the time when the current amplitude in the power stage becomes the maximum (i.e., Imax in FIG. 12B) can be suppressed. Further, the power amplifier circuit 100d2 achieves the same effect as the power amplifier circuit 100d1 with a simpler configuration as compared to the power amplifier circuit 100d1.

### ===Power Amplifier Circuit 100e According to Third Embodiment===

A power amplifier circuit 100e according to a third embodiment will be described below with reference to FIG. 18. FIG. 18 is a diagram showing a configuration example of the power amplifier circuit 100e according to the third embodiment. Note that, in the following, descriptions of common matters with the power amplifier circuit 100a according to the first embodiment will be omitted, and only the differences will be described. In particular, the same effects achieved by the same configuration will not be described repeatedly.

Compared with the power amplifier circuit 100a, the power amplifier circuit 100e is a circuit in which an adjustment circuit 190e suppresses the bias outputted from the bias circuit 130. That is, the power amplifier circuit 100e suppresses the output voltage of the amplifier circuit 150 in the driver stage to thereby prevent the amplifier circuit 160 from being broken.

Since the components of the power amplifier circuit 100e other than the adjustment circuit 190e are the same as those of the power amplifier circuit 100a, the description thereof is omitted.

Specifically, the adjustment circuit 190e includes a transistor 191e and resistors 192e and 193e. The transistor 191e has its base electrically connected to the collector of the transistor 182 through the resistor 192e, its emitter electrically connected to the reference potential, and its collector electrically connected to the bias circuit 130 so as to adjust the bias outputted from the bias circuit 130.

### ===Power Amplifier Circuit 100f According to Fourth Embodiment===

A power amplifier circuit 100f according to a fourth embodiment will be described below with reference to FIG. 19. FIG. 19 is a diagram showing a configuration example of the power amplifier circuit 100f according to the fourth embodiment. In the following, descriptions of common matters with the power amplifier circuit 100a according to the first embodiment will be omitted, and only the differences will be described. In particular, the same effects achieved by the same configuration will not be described repeatedly.

Compared with the power amplifier circuit 100a, the power amplifier circuit 100f includes a transistor 103f and a resistor 104f. The transistor 103f has its base electrically connected to any node (a “node N1” in FIG. 19) between the plurality of diodes of the trigger circuit 170, its collector electrically connected to the collector of the transistor 161 of the amplifier circuit 160 through the resistor 104f, and its emitter electrically connected to the collectors of the transistors 181 and 182 of the conversion circuit 180.

The transistor 103f supplies a signal obtained by amplifying the feedback signal S1 to the conversion circuit 180. That is, in the power amplifier circuit 100f, the conversion circuit 180 is operated by a feedback signal Sf that indicates a current value obtained by dividing the current value of the feedback signal S1 in the power amplifier circuit 100a by a current amplification factor Hfe of the transistor 103f. Thus, in the power amplifier circuit 100f, the conversion circuit 180 is operated by the feedback signal Sf that indicates a current value smaller than the current value of the feedback signal S1. Therefore, the power amplifier circuit 100f can improve the operating sensitivity of the conversion circuit 180.

### <<Fifth Modification>>

A power amplifier circuit 100f1 according to a modification of the fourth embodiment will be described with reference to FIG. 20. FIG. 20 is a diagram showing a configuration example of the power amplifier circuit 100f1 according to a fifth modification. In the following, descriptions of common matters with the power amplifier circuit 100f according to the fourth embodiment will be omitted, and only the differences will be described. In particular, the same effects achieved by the same configuration will not be described repeatedly.

Compared with the power amplifier circuit 100f, the power amplifier circuit 100f1 according to the fifth modification further includes an adjustment circuit 190f1 for suppressing the bias of the amplifier circuit 150 in the driver stage.

The adjustment circuit 190f1 is a circuit for suppressing the bias outputted from the bias circuit 130 to the amplifier circuit 150 in response to the signal S2 inputted from the conversion circuit 180. The adjustment circuit 190f1 includes a transistor 191f1, a resistor 192f1, and a resistor 193f1. Since the adjustment circuit 190f1 has the same configuration as the adjustment circuit 190, the description thereof is omitted.

Next, the operation of the power amplifier circuit 100f1 will be described. The power amplifier circuit 100f1 performs the same operation as the operation performed in the power amplifier circuit 100b1 according to the first modification, which is to suppress the voltage amplitude of the collector and the current amplitude of the base (which differs from the voltage amplitude of the collector in phase by approximately 180 degrees) of the amplifier circuit 160 in the power stage. Therefore, the operation of the power amplifier circuit 100b2 will be described below with reference to FIGS. 12A, 12B and 13.

In the power amplifier circuit 100f1, due to the operation of the conversion circuit 180, the voltage at the time when the voltage amplitude shown in FIG. 12A becomes maximum is suppressed so as to prevent the amplifier circuit 160 in the power stage from being broken. However, the current at the time when the current amplitude shown in FIG. 12B becomes maximum (Imax in FIG. 12B) cannot be suppressed by the conversion circuit 180 and the adjustment circuit 190 provided in the power stage.

Therefore, in the power amplifier circuit 100f1, the adjustment circuit 190f1 is provided in parallel with the adjustment circuit 190, so that when the conversion circuit 180 is operated, the voltage at the time when the voltage amplitude of the amplifier circuit 150 in the driver stage (which differs from the voltage amplitude of the collector of the amplifier circuit 160 in the power stage in phase by approximately 180 degrees) becomes maximum (Vmax 2 in FIG. 13) is suppressed through the adjustment circuit 190f1. Thus, in the power amplifier circuit 100f1, the current at the time when the current amplitude in the power stage becomes maximum (i.e., Imax in FIG. 12B) can be suppressed.

### ===Power Amplifier Circuit 100g According to Fifth Embodiment===

A power amplifier circuit 100g according to a fifth embodiment will be described below with reference to FIG. 21. FIG. 21 is a diagram showing a configuration example of the power amplifier circuit 100g according to the fifth embodiment. In the following, descriptions of the common matters with the power amplifier circuit 100c according to the second embodiment will be omitted, and only the differences will be described. In particular, the same effects achieved by the same configuration will not be described repeatedly.

Compared with the power amplifier circuit 100c, the power amplifier circuit 100g includes a transistor 103g, a resistor 104g, and a capacitor 105g. The transistor 103g has its base electrically connected to any node (a “node Nc1” in FIG. 21) between the plurality of diodes of the trigger circuit 170cl and any node (a “node Nc2” in FIG. 21) between the plurality of diodes of the trigger circuit 170c2, its collector electrically connected to the collector of the transistor 161b of the amplifier circuit 160b through the resistor 104g, and its emitter electrically connected to the collectors of the transistors 181 and 182 of the conversion circuit 180.

The capacitor 105g is a capacitor for smoothing the potential of the collector of the transistor 103g. The capacitor 105g has one end thereof electrically connected to a node (a “node Ng1” in FIG. 21) between the collector of the transistor 103g and the collector of the transistor 161b of the amplifier circuit 160b, and the other end thereof electrically connected to the reference potential. The node Ng1 is provided, for example, between the resistor 104g and the collector of the transistor 103g. Alternatively, the node Ng1 may also be provided, for example, between the resistor 104g and the collector of the transistor 161b.

However, it is preferable that the node Ng1 is provided between the resistor 104g and the collector of the transistor 103g than that the node Ng1 is provided between the resistor 104g and the collector of the transistor 161b. This is because when the node Ng1 is provided between the resistor 104g and the collector of the transistor 103g, the isolation of the capacitor 105g with respect to the path through which the signal RF22 passes is better. Therefore, since the capacitance of the capacitor 105g can be increased, the potential is smoothed more appropriately, and the sensitivity of the breakdown protection function can be increased.

The feedback signal Sc1 rectified by the trigger circuit 170cl and the feedback signal Sc2 rectified by the trigger circuit 170c2 are supplied to the base of the transistor 103g, in which the feedback signal Sc2 is substantially 180 degrees different in phase from the feedback signal Sc1. The transistor 103g supplies a feedback signal Sg to the conversion circuit 180, in which the feedback signal Sg is obtained by amplifying the feedback signal Sc1 and the feedback signal Sc2. Thus, the power amplifier circuit 100g can improve the operating sensitivity of the conversion circuit 180 in the same manner as the power amplifier circuit 100f.

Here, the capacitor 105g smooths the collector voltage of the transistor 103g, which is generated by supplying the feedback signal Sc1 and the feedback signal Sc2 to the base of the transistor 103g. Thus, in the power amplifier circuit 100g, two trigger circuits 170c1 and 170c2 can be made to function by a single transistor 103g.

In contrast, when the capacitor 105g is not provided in the power amplifier circuit 100g, a transistor connected to the trigger circuit 170cl and a transistor connected to the trigger circuit 170c2 must be provided in order to make the two trigger circuits 170cl and 170c2 function. In such a case, the wiring will become complicated to provide the two transistors. That is, by providing the capacitor 105g in the power amplifier circuit 100g, it is possible to reduce the number of transistors and make the two trigger circuits 170c1 and 170c2 function with simple wiring.

### <<Sixth Modification>>

A power amplifier circuit 100g1 according to a modification of the fifth embodiment will be described with reference to FIG. 22. FIG. 22 is a diagram showing a configuration example of the power amplifier circuit 100g1 according to a sixth modification. In the following, descriptions of common matters with the power amplifier circuit 100g according to the fifth embodiment will be omitted, and only the differences will be described. In particular, the same effects achieved by the same configuration will not be described repeatedly.

Compared with the power amplifier circuit 100g, the power amplifier circuit 100g1 according to the sixth modification further includes an adjustment circuit 190g1 for suppressing the bias of the amplifier circuit 150 in the driver stage.

The adjustment circuit 190g1 is a circuit for suppressing the bias outputted from the bias circuit 130 to the amplifier circuit 150 in response to the signal Sg inputted from the conversion circuit 180. The adjustment circuit 190g1 includes a transistor 191g1, a resistor 192g1, and a resistor 193g1. Since the adjustment circuit 190g1 has the same configuration as the adjustment circuit 190, the description thereof is omitted.

Next, the operation of the power amplifier circuit 100g1 will be described. The power amplifier circuit 100g1 performs the same operation as the operation performed in the power amplifier circuit 100d1 according to the third modification, which is to suppress the voltage amplitudes of the collectors and the current amplitudes of the bases (which differ from the voltage amplitudes of the respective collectors in phase by approximately 180 degrees) of the amplifier circuit 160a and the amplifier circuit 160b in the power stage of the power amplifier circuit 100d1 according to the third modification. Therefore, the operation of the power amplifier circuit 100g1 will be described below with reference to FIGS. 12A, 12B and 13.

In the power amplifier circuit 100g1, due to the operation of the conversion circuit 180, the voltage at the time when the voltage amplitude shown in FIG. 12A becomes maximum is suppressed so as to prevent the amplifier circuit 160a and the amplifier circuit 160b in the power stage from being broken. However, the current at the time when the current amplitude shown in FIG. 12B becomes maximum (Imax in FIG. 12B) cannot be suppressed by the conversion circuit 180 and the adjustment circuit 190 provided in the power stage.

Therefore, in the power amplifier circuit 100g1, the adjustment circuit 190g1 is provided in parallel with the adjustment circuit 190, so that when the conversion circuit 180 is operated, the voltage at the time when the voltage amplitude of the amplifier circuit 150 in the driver stage becomes maximized (Vmax 2 in FIG. 13) is suppressed through the adjustment circuit 190g1. Thus, in the power amplifier circuit 100g1, the current at the time when the current amplitude in the power stage becomes maximized (i.e., Imax in FIG. 12B) can be suppressed.

### Summary

<1> A power amplifier circuit 100a according to an exemplary embodiment of the present disclosure includes: an amplifier circuit 160 (first amplifier circuit) to which a first bias is supplied from a bias circuit 140 (first bias circuit), and which amplifies a signal RF1 (first signal) and outputs a signal RFout (output signal) to an output terminal 102 (first output terminal); a trigger circuit 170 (first trigger circuit) that includes at least one diode whose anode is electrically connected to the output terminal 102 (first output terminal), that outputs, when the voltage of the output terminal 102 (first output terminal) exceeds a predetermined threshold, a feedback signal S1 (first feedback signal) corresponding to the voltage of the output terminal 102 (first output terminal); a conversion circuit 180 (first conversion circuit) that includes: a transistor 181 (first transistor) which is diode-connected, a transistor 182 (second transistor) current-mirror connected to the transistor 181 (first transistor), a resistor 183 (first resistor) connected in series to the collector or drain of the transistor 181 (first transistor), a resistor 184 (second resistor) connected in series to the collector or drain of the transistor 182 (second transistor), and a resistor 185 (third resistor) connected in series to the emitter or source of the transistor 182 (second transistor), wherein the feedback signal S1 (first feedback signal) is inputted to the collector or drain of the transistor 181 (first transistor) and the collector or drain of the transistor 182 (second transistor), and the resistance value of the resistor 185 (third resistor) is smaller than the resistance value of the resistor 184 (second resistor); and an adjustment circuit 190 (first adjustment circuit) that includes a transistor 191 of which the base or gate receives a signal S2 outputted from the conversion circuit 180 (first conversion circuit), and of which the collector or drain is electrically connected to the bias circuit 140 (first bias circuit) so as to adjusts the first bias supplied from the bias circuit 140 (first bias circuit). With such a configuration, the power amplifier circuit 100a can achieve high output efficiency while preventing the amplifier circuit from being broken.

<2> The power amplifier circuit 100a according to an exemplary embodiment of the present disclosure is the power amplifier circuit described in <1> in which the adjustment circuit 190 (first adjustment circuit) further includes a resistor 192 (fourth resistor) and a resistor 193 (fifth resistor), and the base or gate of the transistor 191 receives the signal S2 outputted from the conversion circuit 180 (first conversion circuit) through the resistor 192 (fourth resistor), and the collector or drain of the transistor 191 is electrically connected to the bias circuit 140 (first bias circuit) through the resistor 193 (fifth resistor) so as to adjust the first bias supplied from the bias circuit 140 (first bias circuit). With such a configuration, the power amplifier circuit 100a can prevent the amplifier circuit from being broken while isolating the harmonic signal and DC component, and achieve high output efficiency.

<3> The power amplifier circuit 100a according to an exemplary embodiment of the present disclosure is the power amplifier circuit described in <1> or <2>, in which the trigger circuit 170 (first trigger circuit) includes a plurality of diodes 171 and 172 connected in series, in which the anodes of the plurality of diodes 171 are electrically connected to the output terminal 102 (first output terminal), the cathodes of the plurality of diodes 172 are electrically connected to a reference potential, and the feedback signal S1 (first feedback signal) is outputted from a node N1 between two adjacent diodes of the plurality of diodes 171 and 172. With such a configuration, the power amplifier circuit 100a can be protected from ESD, which is a high-voltage spike, by the diodes 172, and can achieve high output efficiency while preventing the amplifier circuit from being broken.

<4> The power amplifier circuit 100a according to an exemplary embodiment of the present disclosure is the power amplifier circuit described in any one of <1> to <3> that further includes: an amplifier circuit 150 (second amplifier circuit) to which a second bias is supplied from a bias circuit 130 (second bias circuit), which is electrically connected, in a stage preceding the amplifier circuit 160 (first amplifier circuit), to the amplifier circuit 160 (first amplifier circuit), and which amplifies a signal RFin (input signal) and outputs the signal RF1 (first signal). With such a configuration, the power amplifier circuit 100a can, in a multi-stage amplifier circuit, achieve high output efficiency while efficiently preventing the amplifier circuit from being broken.

<5> A power amplifier circuit 100b1 according to an exemplary embodiment of the present disclosure is the power amplifier circuit described in <4> that includes: a trigger circuit 170b1 (second trigger circuit) that includes at least one diode whose anode is electrically connected to the collector or drain (second output terminal) of the amplifier circuit 150 (second amplifier circuit), and that outputs, when the voltage of the collector or drain (second output terminal) exceeds a predetermined threshold, a feedback signal Sb1 (second feedback signal) corresponding to the voltage of the collector or drain (second output terminal); a conversion circuit 180b (second conversion circuit) that includes a transistor 181b (third transistor) which is diode-connected, a transistor 182b (fourth transistor) current-mirror connected to the transistor 181b (third transistor), a resistor 183b (sixth resistor) connected in series to the collector or drain of the transistor 181b (third transistor), a resistor 184b (seventh resistor) connected in series to the collector or drain of the transistor 182b (fourth transistor), and a resistor 185b (eighth resistor) connected in series to the emitter or source of the transistor 182b (fourth transistor), wherein the feedback signal Sb1 (second feedback signal) is inputted to the collector or drain of the transistor 181b (third transistor) and the collector or drain of transistor 182b (fourth transistor, and the resistance value of the resistor 185b (eighth resistor) is smaller than the resistance value of the resistor 184b (seventh resistor); and an adjustment circuit 190b (second adjustment circuit) that includes a transistor 191b of which the base or a gate receives a signal outputted from the conversion circuit 180b (second conversion circuit) through a resistor 192b (ninth resistor), and of which the collector or drain is electrically connected to the bias circuit 130 (second bias circuit) through a resistor 193b (tenth resistor) so as to adjust the second bias supplied from the bias circuit 130 (second bias circuit). With such a configuration, the power amplifier circuit 100b1 can suppress the voltage at the time when the current amplitude in the power stage becomes maximum to thereby suppress the current at the time when the voltage amplitude of the amplifier circuit 150 in the driver stage becomes maximum. Therefore, the power amplifier circuit 100b1 can achieve high output efficiency while preventing the amplifier circuit from being broken.

<6> A power amplifier circuit 100c according to an exemplary embodiment of the present disclosure is the power amplifier circuit described in any one of <1> to <5> that further includes: a divider 160c that divides the signal RF1 (first signal) into a signal RF11 (second signal) and a signal RF12 (third signal) having a phase different from the phase of the signal RF11 (second signal) by 180 degrees. The amplifier circuit 160 (first amplifier circuit) includes an amplifier circuit 160a (third amplifier circuit) that amplifies the signal RF11 (second signal) and outputs a signal RFout1 (output signal) to an output terminal 102a (third output terminal), and an amplifier circuit 160b (fourth amplifier circuit) that amplifies the signal RF12 (third signal) and outputs a signal RFout2 (output signal) to an output terminal 102b (fourth output terminal). The trigger circuit 170 (first trigger circuit) includes a trigger circuit 170cl (third trigger circuit), in which the trigger circuit 170cl (third trigger circuit) includes at least one diode whose anode is electrically connected to the output terminal 102a (third output terminal), and outputs, when the voltage of the output terminal 102a (third output terminal) exceeds a predetermined threshold, a feedback signal Sc1 (third feedback signal) corresponding to the voltage of the output terminal 102a (third output terminal), and the trigger circuit 170c2 (fourth trigger circuit) includes at least one diode whose anode is electrically connected to the output terminal 102b (fourth output terminal), and outputs, when the voltage of the output terminal 102b (fourth output terminal) exceeds a predetermined threshold, a feedback signal Sc2 (fourth feedback signal) corresponding to a voltage of the output terminal 102b (fourth output terminal). A signal obtained by combining the feedback signal Sc1 (third feedback signal) and the feedback signal Sc2 (fourth feedback signal) is inputted into the conversion circuit 180 (first conversion circuit) as the feedback signal S1 (first feedback signal). With such a configuration, the power amplifier circuit 100c can be made resistant to noise, and can prevent the amplifier circuit from being broken while achieving miniaturization by using a common conversion circuit.

<7> A power amplifier circuit 100e according to an exemplary embodiment of the present disclosure includes: an amplifier circuit 160 (first amplifier circuit) to which a first bias is supplied from a bias circuit 140 (first bias circuit), and which amplifies a signal RF1 (first signal) and outputs a signal RFout (output signal) to an output terminal 102 (first output terminal); an amplifier circuit 150 (second amplifier circuit) to which a second bias is supplied from a bias circuit 130 (second bias circuit), which is electrically connected, in a stage preceding the amplifier circuit 160 (first amplifier circuit), to the amplifier circuit 160 (first amplifier circuit), and which amplifies a signal RFin (input signal) and outputs the signal RF1 (first signal); a trigger circuit 170 (first trigger circuit) that includes at least one diode whose anode is electrically connected to the output terminal 102 (first output terminal), that outputs, when the voltage of the output terminal 102 (first output terminal) exceeds a predetermined threshold, a feedback signal S1 (first feedback signal) corresponding to the voltage of the output terminal 102a (first output terminal); a conversion circuit 180 (first conversion circuit) that includes: a transistor 181 (first transistor) which is diode-connected, a transistor 182 (second transistor) current-mirror connected to the transistor 181 (first transistor), a resistor 183 (first resistor) connected in series to the collector or drain of the transistor 181 (first transistor), a resistor 184 (second resistor) connected in series to the collector or drain of the transistor 182 (second transistor), and a resistor 185 (third resistor) connected in series to the emitter or source of the transistor 182 (second transistor), wherein the feedback signal S1 (first feedback signal) is inputted to the collector or drain of the transistor 181 (first transistor) and the collector or drain of the transistor 182 (second transistor), and the resistance value of the resistor 185 (third resistor) is smaller than the resistance value of the resistor 184 (second resistor); and an adjustment circuit 190 (first adjustment circuit) that includes a transistor of which the base or gate receives a signal outputted from the conversion circuit 180 (first conversion circuit) through the resistor 192 (fourth resistor), and of which the collector or drain is electrically connected to the bias circuit 130 (second bias circuit) through the resistor 193 (fifth resistor) so as to adjusts the second bias supplied from the bias circuit 130 (second bias circuit). With such a configuration, the power amplifier circuit 100e suppresses the output voltage of the amplifier circuit 150 in the driver stage, thereby preventing the amplifier circuit 160 from being broken.

<8> A power amplifier circuit 100b2, 100d2, 100f1, or 100g1 according to an exemplary embodiment of the present disclosure is the power amplifier circuit described in any one of <1> to <3> that further includes: an amplifier circuit 150 (second amplifier circuit) to which a second bias is supplied from a bias circuit 130 (second bias circuit), which is electrically connected, in a stage preceding the amplifier circuit 160 (first amplifier circuit), to the amplifier circuit 160 (first amplifier circuit), and which amplifies a signal RFin (input signal) and outputs the signal RF1 (first signal); and a second adjustment circuit that includes a transistor 191b2, 191d2, 191f1, or 191g1 of which the base or gate receives a signal outputted from the conversion circuit 180 (first conversion circuit), and of which the collector or drain is electrically connected to the bias circuit 130 (second bias circuit) so as to adjust the second bias supplied from the bias circuit 130 (second bias circuit). With such a configuration, in the power amplifier circuit 100b2, 100d2, 100f1, or 100g1, the voltage and the current at the time when the voltage amplitude and the current amplitude in the power stage become maximized can be suppressed, so that the transistor in the power stage can be prevented from being broken.

Each embodiment described above is intended to facilitate understanding of the present disclosure, and is not intended to limit the interpretation of the present disclosure. The present disclosure may be changed or modified without departing from its scope, and the present disclosure also includes equivalents thereof. That is, appropriate design changes made by those skilled in the art on each embodiment are included in the scope of the present disclosure as long as such design changes include the features of the present disclosure. For example, the elements of each embodiment, as well as the arrangements, materials, conditions, shapes, sizes, and the like of the elements, are not limited to those illustrated above, and may be changed as appropriate. Further, the elements of each embodiment may be combined as long as it is technically possible, and the resulting combinations are also included within the scope of the present disclosure, as long as the combinations include the features of the present disclosure.
100a, 100b1, 100b2, 100c, 100d1, 100d2, 100e, 100f,
100f1, 100g, 100g1 power amplifier circuit
110 matching circuit
120 matching circuit
130 bias circuit
140, 140c bias circuit
150 amplifier circuit
160 amplifier circuit
170, 170b1, 170c1, 170c2, 170d1 trigger circuit
180, 180b, 180d conversion circuit
190, 190b, 190d adjustment circuit

1. A power amplifier circuit comprising:
a first amplifier circuit to which a first bias is supplied from a first bias circuit, and which amplifies a first signal and outputs an output signal to a first output terminal;
a first trigger circuit comprising at least one diode whose anode is electrically connected to the first output terminal, and that outputs a first feedback signal corresponding to the voltage of the first output terminal when a voltage of the first output terminal exceeds a predetermined threshold;
a first conversion circuit comprising: a first transistor which is diode-connected, a second transistor current-mirror connected to the first transistor, a first resistor connected in series to a collector or drain of the first transistor, a second resistor connected in series to a collector or drain of the second transistor, and a third resistor connected in series to an emitter or a source of the second transistor, wherein the first feedback signal is inputted to the collector or drain of the first transistor and the collector or drain of the second transistor, and a resistance value of the third resistor is smaller than a resistance value of the second resistor; and
a first adjustment circuit that comprises a transistor having a base or gate that receives a signal outputted from the first conversion circuit, and having a collector or drain that is electrically connected to the first bias circuit such that the first bias supplied from the first bias circuit is adjusted.

2. The power amplifier circuit according to claim 1,
wherein the first adjustment circuit further comprises a fourth resistor and a fifth resistor, and
wherein the base or gate of the transistor receives the signal outputted from the first conversion circuit through the fourth resistor, and the collector or drain of the transistor is electrically connected to the first bias circuit through the fifth resistor such that the first bias supplied from the first bias circuit is adjusted.

3. The power amplifier circuit according to claim 1,
wherein the first trigger circuit comprises a plurality of diodes connected in series, wherein anodes of the plurality of diodes are electrically connected to the first output terminal, and cathodes of the plurality of diodes are electrically connected to a reference potential, and
wherein the first feedback signal is outputted from a node between two adjacent diodes of the plurality of diodes.

4. The power amplifier circuit according to claim 2,
wherein the first trigger circuit comprises a plurality of diodes connected in series, wherein anodes of the plurality of diodes are electrically connected to the first output terminal, and cathodes of the plurality of diodes are electrically connected to a reference potential, and
wherein the first feedback signal is outputted from a node between two adjacent diodes of the plurality of diodes.

5. The power amplifier circuit according to claim 1, further comprising:
a second amplifier circuit to which a second bias is supplied from a second bias circuit, which is electrically connected to the first amplifier circuit in a stage preceding the first amplifier circuit, and which amplifies an input signal and outputs the first signal.

6. The power amplifier circuit according to claim 2, further comprising:
a second amplifier circuit to which a second bias is supplied from a second bias circuit, which is electrically connected to the first amplifier circuit in a stage preceding the first amplifier circuit, and which amplifies an input signal and outputs the first signal.

7. The power amplifier circuit according to claim 3, further comprising:
a second amplifier circuit to which a second bias is supplied from a second bias circuit, which is electrically connected to the first amplifier circuit in a stage preceding the first amplifier circuit, and which amplifies an input signal and outputs the first signal.

8. The power amplifier circuit according to claim 5, further comprising:
a second trigger circuit that comprises at least one diode whose anode is electrically connected to a second output terminal of the second amplifier circuit, and that outputs a second feedback signal corresponding to the voltage of the second output terminal when a voltage of the second output terminal exceeds a predetermined threshold;
a second conversion circuit that comprises a third transistor which is diode-connected, a fourth transistor current-mirror connected to the third transistor, a sixth resistor connected in series to a collector or drain of the third transistor, a seventh resistor connected in series to a collector or drain of the fourth transistor, and an eighth resistor connected in series to an emitter or a source of the fourth transistor, wherein the second feedback signal is inputted to the collector or drain of the third transistor and the collector or drain of the fourth transistor, and a resistance value of the eighth resistor is smaller than a resistance value of the seventh resistor; and
a second adjustment circuit that comprises a transistor having a base or gate that receives a signal outputted from the second conversion circuit through a ninth resistor, and having a collector or drain that is electrically connected to the second bias circuit through a tenth resistor such that the second bias supplied from the second bias circuit is adjusted.

9. The power amplifier circuit according to claim 1, further comprising:
a divider that divides the first signal into a second signal and a third signal having a phase different from a phase of the second signal by 180 degrees,
wherein the first amplifier circuit comprises a third amplifier circuit that amplifies the second signal and outputs a first output signal to a third output terminal, and a fourth amplifier circuit that amplifies the third signal and outputs a second output signal to a fourth output terminal,
wherein the first trigger circuit comprises a third trigger circuit and fourth trigger circuit,
wherein the third trigger circuit comprises at least one diode whose anode is electrically connected to the third output terminal, and outputs a third feedback signal corresponding to the voltage of the third output terminal when a voltage of the third output terminal exceeds a predetermined threshold,
wherein the fourth trigger circuit comprises at least one diode whose anode is electrically connected to the fourth output terminal, and outputs a fourth feedback signal corresponding to the voltage of the fourth output terminal when a voltage of the fourth output terminal exceeds a predetermined threshold, and
wherein a signal obtained by combining the third feedback signal and the fourth feedback signal is inputted into the first conversion circuit as the first feedback signal.

10. The power amplifier circuit according to claim 8, further comprising:
a divider that divides the first signal into a second signal and a third signal having a phase different from a phase of the second signal by 180 degrees,
wherein the first amplifier circuit comprises a third amplifier circuit that amplifies the second signal and outputs a first output signal to a third output terminal, and a fourth amplifier circuit that amplifies the third signal and outputs a second output signal to a fourth output terminal,
wherein the first trigger circuit comprises a third trigger circuit and fourth trigger circuit,
wherein the third trigger circuit comprises at least one diode whose anode is electrically connected to the third output terminal, and outputs a third feedback signal corresponding to the voltage of the third output terminal when a voltage of the third output terminal exceeds a predetermined threshold,
wherein the fourth trigger circuit comprises at least one diode whose anode is electrically connected to the fourth output terminal, and outputs a fourth feedback signal corresponding to the voltage of the fourth output terminal when a voltage of the fourth output terminal exceeds a predetermined threshold, and
wherein a signal obtained by combining the third feedback signal and the fourth feedback signal is inputted into the first conversion circuit as the first feedback signal.

11. A power amplifier circuit comprising:
a first amplifier circuit to which a first bias is supplied from a first bias circuit, and which amplifies a first signal and outputs an output signal to a first output terminal;
a second amplifier circuit to which a second bias is supplied from a second bias circuit, which is electrically connected to the first amplifier circuit in a stage preceding the first amplifier circuit, and which amplifies an input signal and outputs the first signal;
a first trigger circuit that comprises at least one diode whose anode is electrically connected to the first output terminal, and that outputs a first feedback signal corresponding to the voltage of the first output terminal when a voltage of the first output terminal exceeds a predetermined threshold;
a first conversion circuit that comprises a first transistor which is diode-connected, a second transistor current-mirror connected to the first transistor, a first resistor connected in series to a collector or drain of the first transistor, a second resistor connected in series to a collector or drain of the second transistor, and a third resistor connected in series to an emitter or a source of the second transistor, wherein the first feedback signal is inputted to the collector or drain of the first transistor and the collector or drain of the second transistor, and a resistance value of the third resistor is smaller than a resistance value of the second resistor; and
a first adjustment circuit that comprises a transistor having a base or gate that receives a signal outputted from the first conversion circuit, and having a collector or drain that is electrically connected to the second bias circuit such that the second bias supplied from the second bias circuit is adjusted.

12. The power amplifier circuit according to claim 1, further comprising:
a second amplifier circuit to which a second bias is supplied from a second bias circuit, which is electrically connected to the first amplifier circuit in a stage preceding the first amplifier circuit, and which amplifies an input signal and outputs the first signal; and
a second adjustment circuit that comprises a transistor having a base or gate that receives a signal outputted from the first conversion circuit, and having a collector or drain that is electrically connected to the second bias circuit such that the second bias supplied from the second bias circuit is adjusted.

13. The power amplifier circuit according to claim 2, further comprising:
a second amplifier circuit to which a second bias is supplied from a second bias circuit, which is electrically connected to the first amplifier circuit in a stage preceding the first amplifier circuit, and which amplifies an input signal and outputs the first signal; and
a second adjustment circuit that comprises a transistor having a base or gate that receives a signal outputted from the first conversion circuit, and having a collector or drain that is electrically connected to the second bias circuit such that the second bias supplied from the second bias circuit is adjusted.

14. The power amplifier circuit according to claim 3, further comprising:
a second amplifier circuit to which a second bias is supplied from a second bias circuit, which is electrically connected to the first amplifier circuit in a stage preceding the first amplifier circuit, and which amplifies an input signal and outputs the first signal; and
a second adjustment circuit that comprises a transistor having a base or gate that receives a signal outputted from the first conversion circuit, and having a collector or drain that is electrically connected to the second bias circuit such that the second bias supplied from the second bias circuit is adjusted.
